(19) United States
(12) Patent Application Publication
(10) Pub. No.: US 2026/0156893 A1
(43) Pub. Date: Jun. 4, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Jung-Hung CHANG, Hsinchu (TW); Tsung-Han CHUANG, Hsinchu (TW); Chien Ning YAO, Hsinchu (TW); Chia-Cheng TSAI, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/964,106

(22) Filed: Nov. 29, 2024

(51) Int. Cl. H10D 64/01; H10D 30/01; H10D 30/43; H10D 30/67; H10D 30/69; H10D 62/10; H10D 64/23; H10D 84/01; H10D 84/03; H10D 84/83

(52) U.S. Cl. CPC H10D 64/017; H10D 30/014; H10D 30/43; H10D 30/6735; H10D 30/6757; H10D 30/797; H10D 62/121; H10D 64/018; H10D 64/021; H10D 64/258; H10D 84/0128; H10D 84/013; H10D 84/038; H10D 84/8312

(57) ABSTRACT

A semiconductor structure includes a substrate, a plurality of active channels and a source/drain layer. The substrate has a front surface and an epitaxial crystal orientation of (110) indicated by a miller index, wherein the epitaxial crystal orientation is perpendicular to the front surface. The active channels are disposed on the substrate and vertically stacked to each other, wherein each active channel has a lateral surface. The source/drain layer covers the lateral surfaces of the active channels.

### BACKGROUND

For N-FET (N-type transistor) device, the n-mobility (electron mobility) may be boost with tensile stressor on channel, and N-EPI (N-type epitaxy) with stressor is one of the approaches. Since the SiGe has larger lattice distance, the SiGe layer may provide tensile stressor to channel when SiGe grow from sidewall of active sheet. However, the SiGe layer is higher resistance material for N-FET.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1a illustrates a schematic diagram of a cross-sectional view of a local portion of a semiconductor structure 100 along a X-Z plane according to an embodiment of the present disclosure;

FIG. 1b illustrates a schematic diagram of a cross-sectional view of the local portion of the semiconductor structure 100 along a Y-Z plane;

FIG. 2a illustrates a schematic diagram of a cross-sectional view of a local portion of a semiconductor structure 200 along a X-Z plane according to an embodiment of the present disclosure;

FIG. 2b illustrates a schematic diagram of a cross-sectional view of the local portion of the semiconductor structure 200 along a Y-Z plane;

FIG. 3a illustrates a schematic diagram of a cross-sectional view of a local portion of a semiconductor structure 300 along a X-Z plane according to an embodiment of the present disclosure;

FIG. 3b illustrates a schematic diagram of a cross-sectional view of the local portion of the semiconductor structure 300 along a Y-Z plane;

FIG. 4A_a to 4P_b illustrate schematic diagrams of manufacturing processes of the semiconductor structure 100 in FIGS. 1a to 1b;

FIG. 5A_a to 5P_b illustrate schematic diagrams of manufacturing processes of the semiconductor structure 200 in FIGS. 2a to 2b; and

FIG. 6A_a to 6I_b illustrate schematic diagrams of manufacturing processes of the semiconductor structure 300 in FIGS. 3a to 3b.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

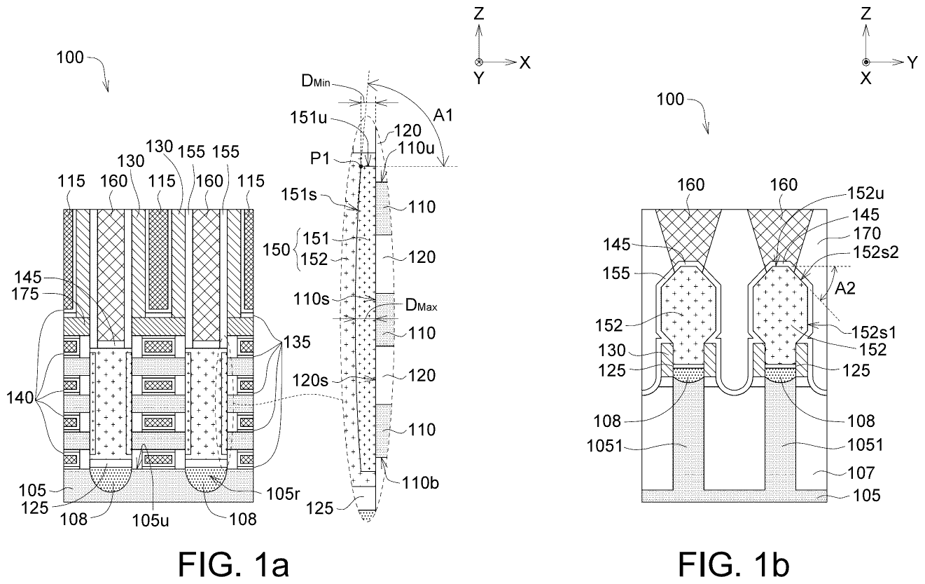

As illustrated in FIGS. 1a and 1b, FIG. 1a illustrates a schematic diagram of a cross-sectional view of a local portion of a semiconductor structure 100 along a X-Z plane according to an embodiment of the present disclosure, and FIG. 1b illustrates a schematic diagram of a cross-sectional view of the local portion of the semiconductor structure 100 along a Y-Z plane. The semiconductor structure 100 may include a plurality of transistors having Gate-all-around (GAA) structure or silicon nanosheet structure.

As illustrated in FIGS. 1a and 1b, the semiconductor structure 100 includes a substrate 105, an oxide layer 107, a plurality of silicon epitaxy 108, a plurality of active channels (or active channel sheets) 110, a plurality of metal gates 115, a plurality of inner spacers 120, a plurality of isolation layers 125, a plurality of gate spacers 130, a plurality of first dielectric layers 135, a plurality of second dielectric layers 140, a plurality of silicide layers 145, a plurality of source/drain layers 150, a plurality of contact etching stop layers (CESLs) 155, a plurality of contacts 160, an interlayer dielectric (ILD) 170 and a plurality of protection layers 175.

As illustrated in FIGS. 1a and 1b, in the present embodiment, the active channels 110 are vertically stacked to each other, wherein each active channel 110 has a lateral surface 110s. The source/drain layer 150 includes a first source/drain portion 151 and a second source/drain portion 152. The first source/drain portion 151 covers the lateral surfaces 110s of the active channel 110. The first source/drain portion 151 has the maximum outer diameter (or maximum outer size) D_{Max} (for example, in X-axis) and the minimum outer diameter (or minimum outer size) D_{Min} (for example, in X-axis), and a ratio of the maximum outer diameter D_{Max} to the minimum outer diameter D_{Min} may be less than 1.1, or even greater or less.

In an embodiment, the maximum outer diameter D_{Max} may range between 1 nanometer (nm) and 8 nanometers, or even greater or less, for example, 7 nm, 6 nm, 5 nm, 4 nm, 3 nm, 2 nm, etc.

As illustrated in FIGS. 1a to 1b, the substrate 105 is, for example, a portion of a silicon wafer. The substrate 105 has an upper surface (for example, front surface) 105u and a recess 105r recessed relative to the upper surface 105u. The substrate 105 includes at least one active region (or referred to as an oxide definition (OD) region) 1051. The active region 1051 extends in X-axis. In the present embodiment, the substrate 105 has an epitaxial crystal orientation of a (110) indicated by a miller index, wherein the epitaxial crystal orientation is perpendicular to the upper surface 105u. Due to the substrate 105 with the epitaxial crystal orientation of (110) being selected, the first source/drain portion 151 may be shaped as the geometric shape as illustrated in FIG. 1a.

As illustrated in FIG. 1b, the oxide layer 107 is formed on a lateral surface of the active regions 1051. In an embodiment, the oxide layer 107 is, for example, a Shallow Trench Isolation (STI) layer.

As illustrated in FIG. 1a, the active channel 110 may be formed of, for example, silicon. The active channel 110 may be referred to as “nanosheet”. The silicon epitaxy 108 is disposed within a wall of the recess 105r.

As illustrated in FIG. 1a, the metal gate 115 is disposed on the active channel 110 and between the adjacent two active channels 110. By way of example, the metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the metal gate 115 may be formed by ALD, PVD, CVD, e-beam evaporation, or other suitable process. Further, the metal gate 115 may be formed separately for n-type transistors and p-type transistors, which may use different metal layers (e.g., for providing different n-type and p-type work function metal layers).

As illustrated in FIG. 1a, the inner spacer 120 is disposed adjacent to a lateral surface of the metal gate 115, a lateral surface of the first dielectric layer 135 and/or a lateral surface of the second dielectric layer 140.

As illustrated in FIG. 1a, the isolation layer (or referred to as a flexible bottom insulator (FBI)) 125 is disposed over the silicon epitaxy 108. The isolation layer 125 is formed of, for example, a dielectric material. The isolation layer 125 may electrically isolate the substrate 110 from the source/drain layer 150. The isolation layer 125 may be configured to include a dielectric material that has, for example, aluminum (Al), titanium (Ti), lithium (Li), hafnium (Hf), zirconium (Zr), lanthanum (La), molybdenum (Mo), cobalt (Co), silicon (Si), oxygen (0), nitrogen (N), carbon (C), any other suitable elements, or combinations thereof. In some embodiments, the isolation layer 125 may include a low-k dielectric material having a k parameter less than about 3.9. As described later, the isolation layer 125 separates two adjacent source/drain features, and having a low k parameter improves the isolation therebetween. In some embodiments, the isolation layer 125 may be silicon nitride, silicon carbonitride, silicon oxynitride, silicon carboxynitride, or combinations thereof. Any suitable methods may be used to form the isolation layer 125. In the depicted embodiments, the isolation layer 125 is formed using ALD, CVD, PVD, other suitable methods, or combinations thereof.

As illustrated in FIG. 1a, the gate spacer 130 may be a multi-layered structure or a single-layered structure. For the multi-layered structure, the gate spacer 130 includes a first-sub spacer portion and a second-sub spacer portion. The second-sub spacer portion is disposed between the metal gate and the first-sub spacer portion. In terms of material, the first-sub spacer portion may be formed of one of SiO, SiN, SiOC, SiON, SiOCN, etc., the second-sub spacer portion may be formed of another of SiO, SiN, SiOC, SiON, SiOCN, etc.

As illustrated in FIG. 1a, the first dielectric layers 135 are formed on the active channels 110. In an embodiment, the first dielectric layer 135 is, for example, an interface layer (IL). The first dielectric layer 135 may be deposited by any appropriate method, such as ALD, CVD, and/or PVD. The first dielectric layer 135 may include silicon oxide (SiO2), or silicon oxynitride (SiON).

As illustrated in FIG. 1a, the second dielectric layers 140 are formed on the first dielectric layers 135 and the inner spacer 120 are formed by using, for example, deposition, such as ALD, CVD, metal-organic CVD, PVD, or a combination thereof. The second dielectric layer 140 is, for example, High-k gate dielectric layer. The High-k gate dielectric layer HK may be formed of a material including: (i) a high-k dielectric material, such as hafnium oxide (HfO₂), titanium oxide (TiO₂), hafnium zirconium oxide (HfZrO), tantalum oxide (Ta2O3), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIGS. 1a and 1b, the silicide layers 145 are formed over the exposed source/drain layers 150. The source/drain layer 150 may be formed over the isolation layer 125. The source/drain layer 150 may be a source region or a drain region of a transistor, wherein the transistor is, for example, N-type transistor. In some embodiments, the forming of the silicide layers 145 includes annealing to induce a chemical interaction between the conductive materials of the contact 160 and the source/drain layer 150 (source/drain features).

In the present embodiment, the first source/drain portion 151 is formed of high resistance material (its property tends to P-type semiconductor material), and thus it is not good for the electron mobility of the N-type transistor. However, the size ratio of the first source/drain portion 151 in the present embodiment may apply a greater tensile stress to the active channels 110, and thus it is conducive to the electron mobility of the N-type transistor.

The source/drain layer 150 may include one or more layers of epitaxially grown material. For example, a deposition tool may epitaxially grow a first layer (for example, the first source/drain portion 151, and may be referred to as an L1) of the source/drain layer 150 over the silicon material, and may epitaxially grow a second layer (for example, the second source/drain portion 152, and may be referred to as an L2, an L2-1, and/or an L2-2) of the source/drain layer 150 over the first layer. The first layer may include a lightly doped silicon (e.g., doped with boron (B), phosphorous (P), and/or another dopant), and may be included as shielding layer to reduce short channel effects in the semiconductor structure (or device) and to reduce dopant extrusion or migration into the active channels. The second layer may include a highly doped silicon or highly doped SiGe. The second layer may be included to provide a compressive stress in the source/drain layer 150 to reduce boron loss.

As illustrated in FIG. 1a, the first source/drain portion 151 is, for example, a single and contiguous layer, for example. Furthermore, the first source/drain portion 151 may extend contiguously from the topmost active channel 110 from the bottommost active channel 110. In an embodiment, the first source/drain portion 151 may protrude relative to an upper surface 110u of the topmost active channel 110, and protrude relative to a lower surface 110b of the bottommost active channel 110. In addition, each inner spacer 120 has a lateral surface 120s, wherein the first source/drain portion 151 covers at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120. In the present embodiment, the first source/drain portion 151 may be in contact with at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120.

In addition, as illustrated in FIG. 1a, the first source/drain portion 151 has an upper surface 151u, and the upper surface 151u is substantially parallel to the OD direction (for example, X-axis). In addition, the first source/drain portion 151 has a lateral surface 151s, wherein the minimum included angle A1 between a tangential of any point P1 (for example, a connection point between the upper surface 151u and the lateral surface 151s) of the lateral surface 151s and a horizontal axis (for example, X-axis) may be equal to or greater than 60 degrees, 70 degrees, 80 degrees, 90 degrees, or a real number ranging 60 degrees and 90 degrees. In terms of material, the first source/drain portion 151 may be formed of, for example, silicon germanium (SiGe) or SiGe with dopant Arsenic (As) or Phosphorus (P), for example, SiGeAs or SiGeP. The first source/drain portion 151 is used as N-stressor and prevents Rcsd (that is, the resistance of current flow between the epitaxial source/drain structure and the source/drain contacts). The performance of N-FET will be boost by the first source/drain portion 151 which is as a tensile stressor.

As illustrated in FIG. 1a, the second source/drain portion 152 is disposed over the isolation layers 125 and covers the first source/drain portion 151. In terms of material, the second source/drain portion 152 may be formed of, for example, SiAs or SiP. The first source/drain portion 151 and the second source/drain portion 152 may be formed in an epitaxial process, such as VPE, UHV-CVD, MBE, and/or other suitable processes. Due to the substrate 105 with the epitaxial crystal orientation of (110) being selected, the second source/drain portion 152 may form a specific degrees. Furthermore, the second source/drain portion 152 has an upper surface 152u, a lateral surface 152s1 and an inclined surface 152s2, wherein the inclined surface 152s2 connects the upper surface 152u with the lateral surface 152s1, and an included angle A2 between the upper surface 152u and the inclined surface 152s2 may be less than 40 degrees, for example, 35.3 degrees.

As illustrated in FIGS. 1a and 1b, the CESL 155 is formed on the source/drain layer 150 and the gate spacer 130. The contact 160 is formed over the silicide layer 145, the CESL 155 and the source/drain layer 150. The contacts 160 may be formed of a metal including the material the same as or similar to that of the metal gate 115. The ILD 170 is formed over the CESL 155 and has a plurality of holes exposing the silicide layers 145. The contacts 160 are formed within the holes of the ILD 170.

As illustrated in FIG. 1a, the protection layer 175 is disposed between the topmost inner spacer 120 and the gate spacer 130 for preventing the first source/drain portion 151 being contact with the gate spacer 130. Furthermore, if the protection layer 175 is omitted, the first source/drain portion 151 may extend to a lateral surface of the gate spacer 130, the tensile stress of the first source/drain portion 151 to the active channels 110 will be reduced due to the gate spacer 130 having a higher stress resistance. In an embodiment, the protection layer 175 may be formed of a material the same as or the similar to that of the gate spacer 130.

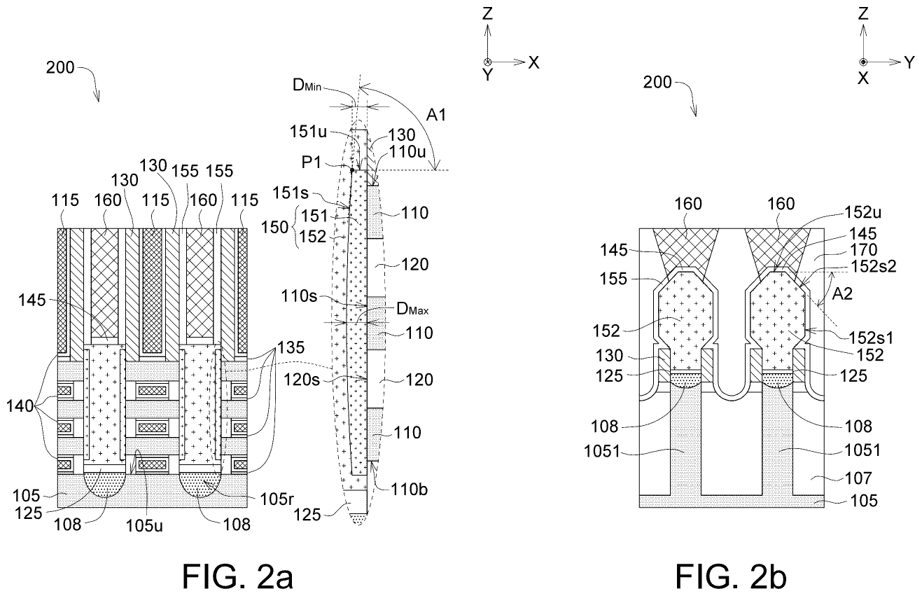

As illustrated in FIGS. 2a and 2b, FIG. 2a illustrates a schematic diagram of a cross-sectional view of a local portion of a semiconductor structure 200 along a X-Z plane according to an embodiment of the present disclosure, and FIG. 2b illustrates a schematic diagram of a cross-sectional view of the local portion of the semiconductor structure 200 along a Y-Z plane. The semiconductor structure 200 may include a plurality of transistors having Gate-all-around (GAA) structure or silicon nanosheet structure.

As illustrated in FIGS. 2a and 2b, the semiconductor structure 200 includes the substrate 105, the oxide layer 107, the silicon epitaxy 108, a plurality of the active channels 110, a plurality of the metal gates 115, a plurality of the inner spacers 120, a plurality of the isolation layers 125, a plurality of the gate spacers 130, a plurality of the first dielectric layers 135, a plurality of the second dielectric layers 140, a plurality of the silicide layers 145, a plurality of the source/drain layers 150, a plurality of the contact etching stop layers 155, a plurality of the contacts 160, and the interlayer dielectric 170.

As illustrated in FIGS. 2a and 2b, in the present embodiment, the active channels 110 are vertically stacked to each other, wherein each active channel 110 has the lateral surface 110s. The source/drain layer 150 includes the first source/drain portion 151 and a second source/drain portion 152. The first source/drain portion 151 covers the lateral surfaces 110s of the active channel 110. The first source/drain portion 151 has the maximum outer diameter (or maximum outer size) D_{Max} (for example, in X-axis) and the minimum outer diameter (or minimum outer size) D_{Min} (for example, in X-axis), and a ratio of the maximum outer diameter D_{Max} to the minimum outer diameter D_{Min} may be less than 1.1, or even greater or less. In another embodiment, the ratio of the maximum outer diameter D_{Max} to the minimum outer diameter D_{Min} may be a real number equal to or greater than 1.

The semiconductor structure 200 includes the features the same as or similar to that of the semiconductor structure 100, and at least one difference is that the semiconductor structure 200 may omit the protection layers 175, the topmost active channel 110, the topmost first dielectric layer 135 and the topmost second dielectric layer 140 in FIG. 1a. Accordingly, the first source/drain portion 151 may extend to a lateral surface of the gate spacer 130.

In the present embodiment, the first source/drain portion 151 is formed of high resistance material (its property tends to P-type semiconductor material), and thus it is not good for the electron mobility of the N-type transistor. However, the size ratio of the first source/drain portion 151 in the present embodiment may apply a greater tensile stress to the active channels 110, and thus it is conducive to the electron mobility of the N-type transistor.

As illustrated in FIG. 2a, the first source/drain portion 151 is, for example, a single and contiguous layer, for example. Furthermore, the first source/drain portion 151 may extend contiguously from the topmost active channel 110 from the bottommost active channel 110. In an embodiment, the first source/drain portion 151 may protrude relative to an upper surface 110u of the topmost active channel 110, and protrude relative to a lower surface 110b of the bottommost active channel 110. In addition, each inner spacer 120 has the lateral surface 120s, wherein the first source/drain portion 151 covers at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120. In the present embodiment, the first source/drain portion 151 may be in contact with at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120.

In addition, as illustrated in FIG. 2a, the first source/drain portion 151 has the upper surface 151u, and the upper surface 151u is substantially parallel to the OD direction (for example, X-axis). In addition, the first source/drain portion 151 has the lateral surface 151s, wherein the minimum included angle A1 between the tangential of any point P1 (for example, the connection point between the upper surface 151u and the lateral surface 151s) of the lateral surface 151s and a horizontal axis (for example, X-axis) may be equal to or greater than 60 degrees, 70 degrees, 80 degrees, 90 degrees, or a real number ranging 60 degrees and 90 degrees. In terms of material, the first source/drain portion 151 may be formed of, for example, SiGe (Silicon-germanium), SiGeAs or SiGeP.

As illustrated in FIG. 2a, the second source/drain portion 152 is disposed over the isolation layers 125 and covers the first source/drain portion 151. In terms of material, the second source/drain portion 152 may be formed of, for example, SiAs or SiP. The first source/drain portion 151 and the second source/drain portion 152 may be formed in an epitaxial process, such as VPE, UHV-CVD, MBE, and/or other suitable processes. Due to the substrate 105 with the epitaxial crystal orientation of (110) being selected, the second source/drain portion 152 may form a specific degrees. Furthermore, the second source/drain portion 152 has the upper surface 152u, the lateral surface 152s1 and the inclined surface 152s2, wherein the inclined surface 152s2 connects the upper surface 152u with the lateral surface 152s1, and an included angle A2 between the upper surface 152u and the inclined surface 152s2 may be less than 40 degrees, for example, 35.3 degrees.

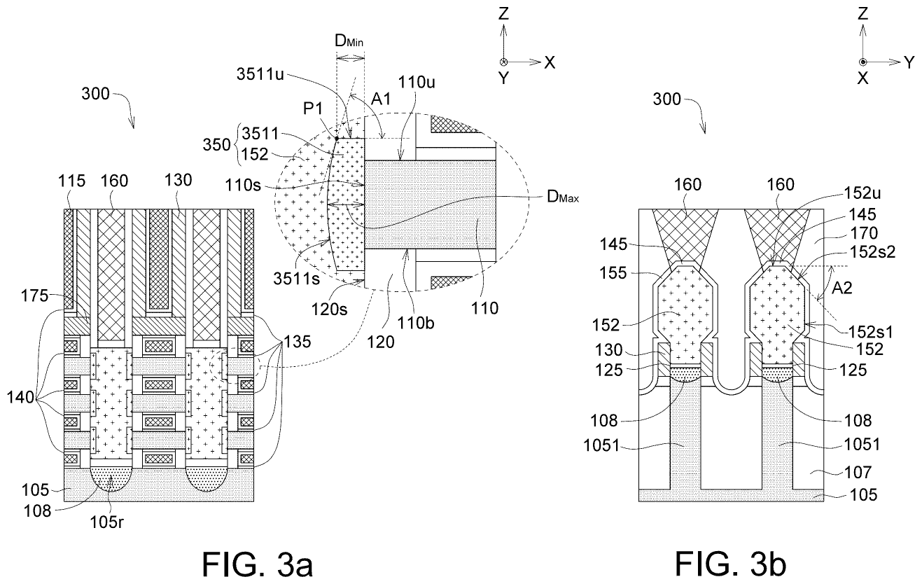

Referring to FIGS. 3a and 3b, FIG. 3a illustrates a schematic diagram of a cross-sectional view of a local portion of a semiconductor structure 300 along a X-Z plane according to an embodiment of the present disclosure, and FIG. 3b illustrates a schematic diagram of a cross-sectional view of the local portion of the semiconductor structure 300 along a Y-Z plane. The semiconductor structure 300 may include a plurality of transistors having Gate-all-around structure or silicon nanosheet structure.

As illustrated in FIG. 3, the semiconductor structure 300 includes the substrate 105, the oxide layer 107, the silicon epitaxy 108, a plurality of the active channels 110, a plurality of the metal gates 115, a plurality of the inner spacers 120, a plurality of the isolation layers 125, a plurality of the gate spacers 130, a plurality of the first dielectric layer 135, a plurality of the second dielectric layers 140, a plurality of the silicide layers 145, a plurality of the epitaxies 350, a plurality of the contact etching stop layers 155, a plurality of the contacts 160, the interlayer dielectric 170 and a plurality of the protection layers 175.

As illustrated in FIG. 3, in the present embodiment, the active channels 110 are vertically stacked to each other, wherein each active channel 110 has the lateral surface 110s. The source/drain layer 350 includes a first source/drain portion 351 and a second source/drain portion 152. The first source/drain portion 351 covers the lateral surfaces 110s of the active channel 110. The first source/drain portion 351 has the maximum outer diameter (or maximum outer size) D_{Max} (for example, in X-axis) and the minimum outer diameter (or minimum outer size) D_{Min} (for example, in X-axis), and a ratio of the maximum outer diameter D_{Max} to the minimum outer diameter D_{Min} may be less than 1.1, or even greater or less.

The semiconductor structure 300 includes the features the same as or similar to that of the semiconductor structure 100, and at least one difference is that the first source/drain portion 351 of the semiconductor structure 300 may include a plurality of plurality of sub-epitaxial portions which are separated from each other.

As illustrated in FIG. 3, the first source/drain portion 351 includes a plurality of sub-source/drain portions 3511, wherein the sub-source/drain portions 3511 are separated from each other. Each sub-source/drain portion 3511 is disposed on the entirety of the lateral surface 110s of the corresponding the active channel 110 and a portion of the lateral surface 120s of the corresponding inner spacer 120.

In the present embodiment, the first source/drain portion 351 is formed of high resistance material (its property tends to P-type semiconductor material), and thus it is not good for the electron mobility of the N-type transistor. However, the size ratio of the first source/drain portion 351 may apply a greater tensile stress to the active channels 110, and thus it is conducive to the electron mobility of the N-type transistor. The first source/drain portion 351 may be formed of a material the same as or similar to that of the first source/drain portion 151.

As illustrated in FIG. 3, each sub-source/drain portion 3511 may protrude relative to the upper surface 110u of the corresponding active channel 110, and protrude relative to the lower surface 110b of the corresponding active channel 110. In addition, each inner spacer 120 has the lateral surface 120s, wherein each sub-source/drain portion 3511 covers at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120. In the present embodiment, each sub-source/drain portion 3511 may be in contact with at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120.

In addition, as illustrated in FIG. 3, each sub-source/drain portion 3511 has a upper surface 3511u, and the upper surface 3511u is substantially parallel to the OD direction (for example, X-axis). In addition, each sub-source/drain portion 3511 has a lateral surface 3511s, wherein the minimum included angle A1 between the tangential of any point P1 (for example, the connection point between the upper surface 3511u and the lateral surface 3511s) of the lateral surface 3511s and a horizontal axis (for example, X-axis) may be equal to or greater than 60 degrees, 70 degrees, 80 degrees, 90 degrees, or a real number ranging 60 degrees and 90 degrees.

As illustrated in FIG. 3, the second source/drain portion 152 is disposed over the isolation layers 125 and covers the sub-source/drain portions 3511. In terms of material, the second source/drain portion 152 may be formed of, for example, SiAs or SiP. The first source/drain portion 351 and the second source/drain portion 152 may be formed in an epitaxial process, such as VPE, UHV-CVD, MBE, and/or other suitable processes.

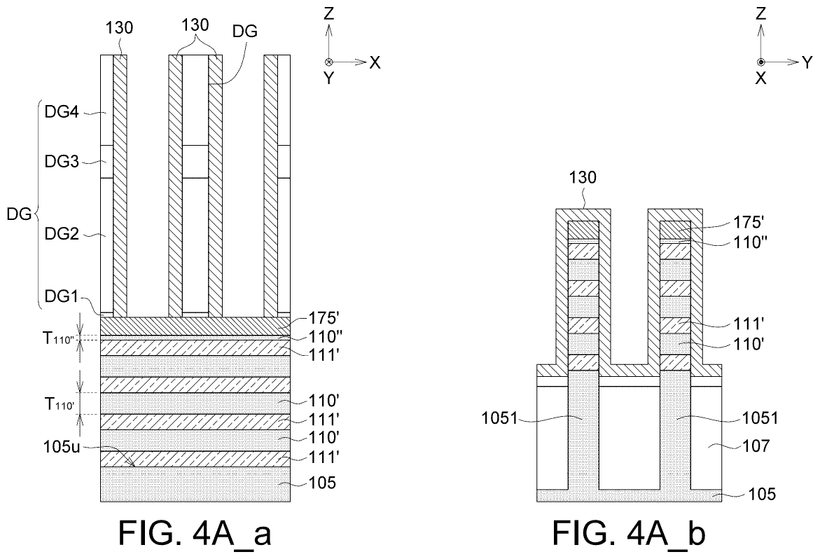

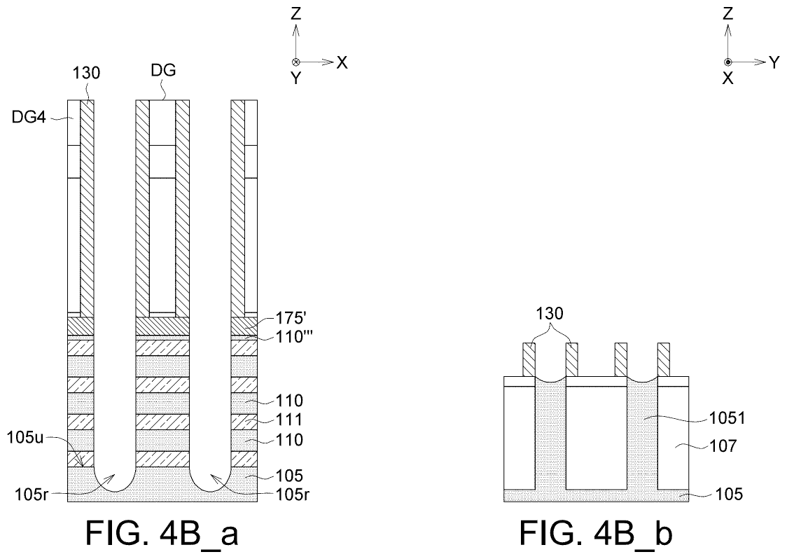

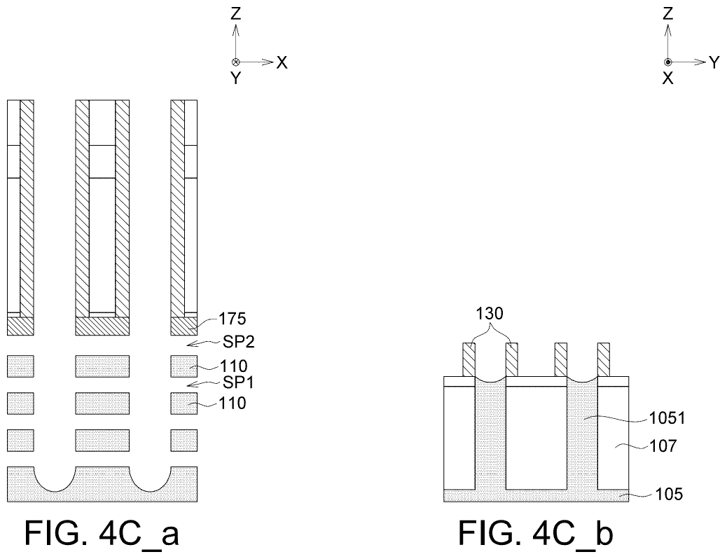

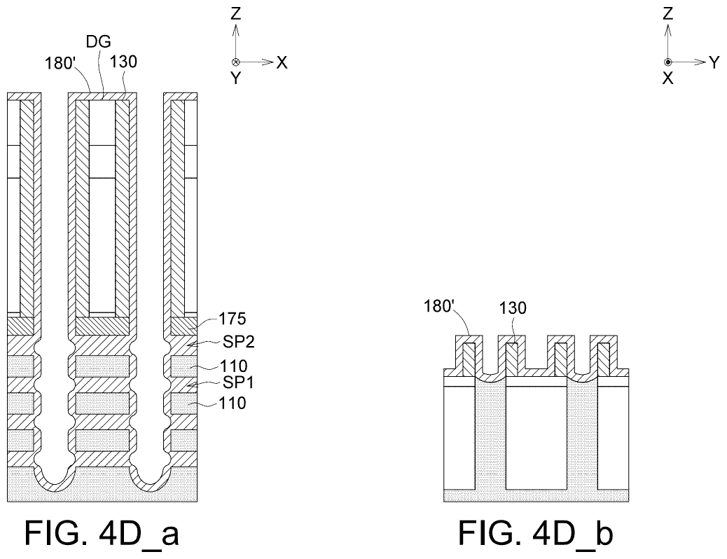

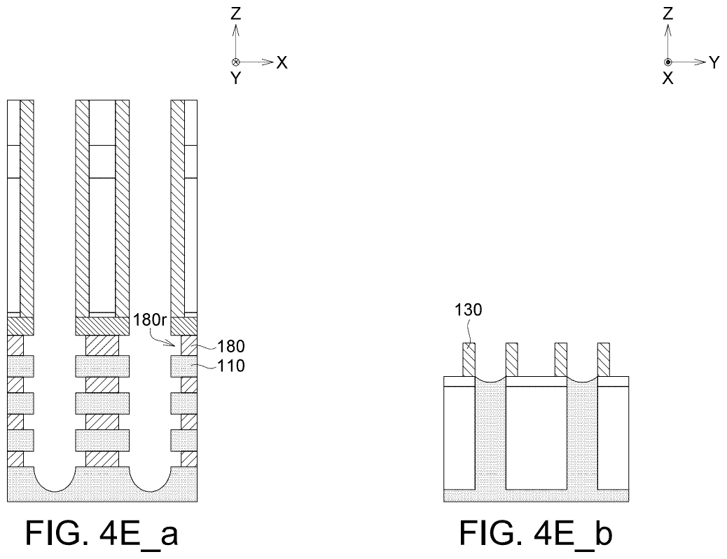

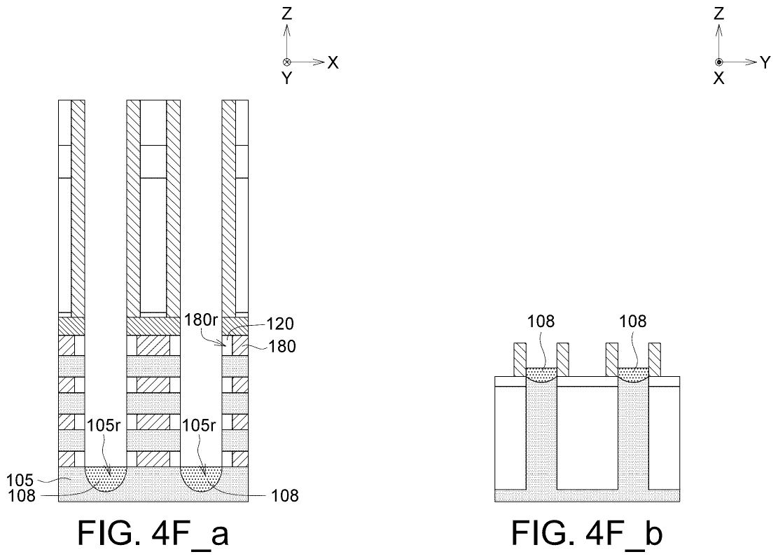

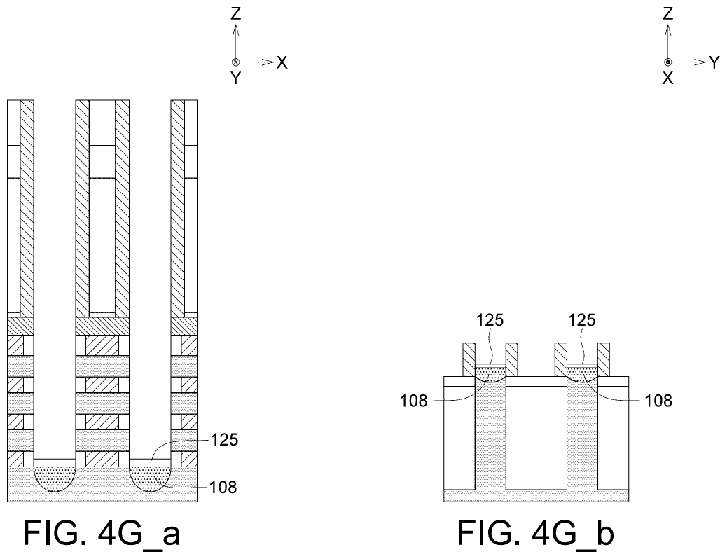

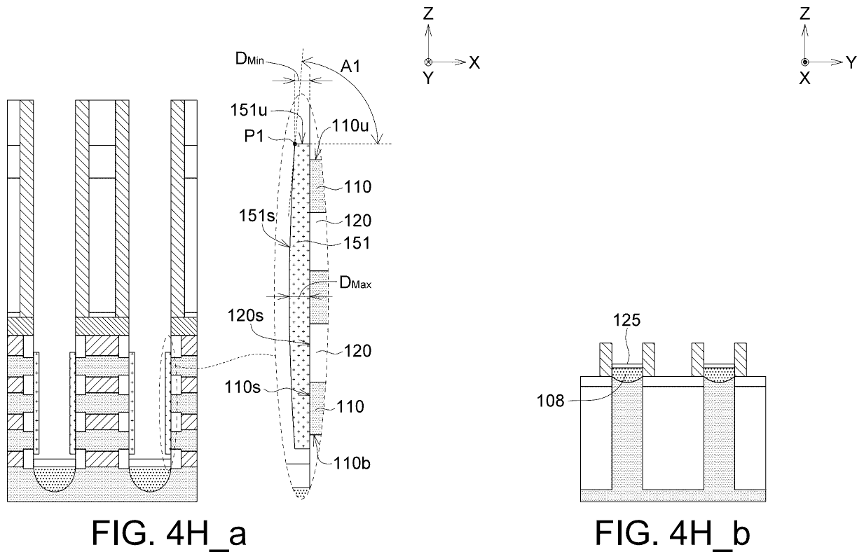

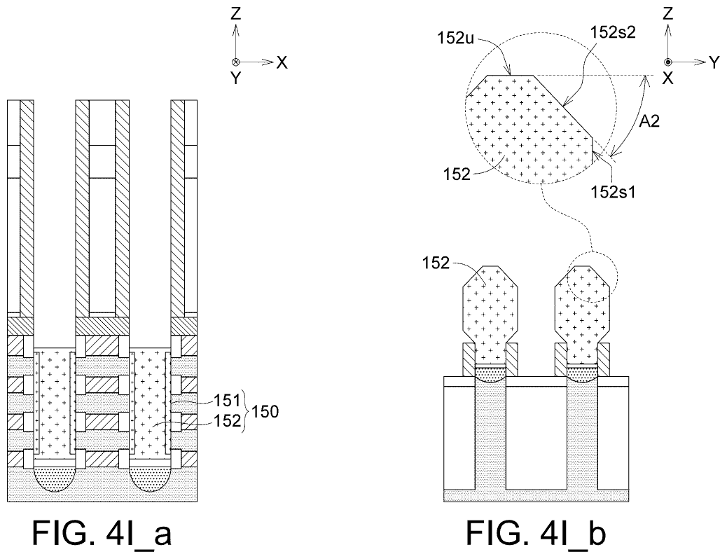

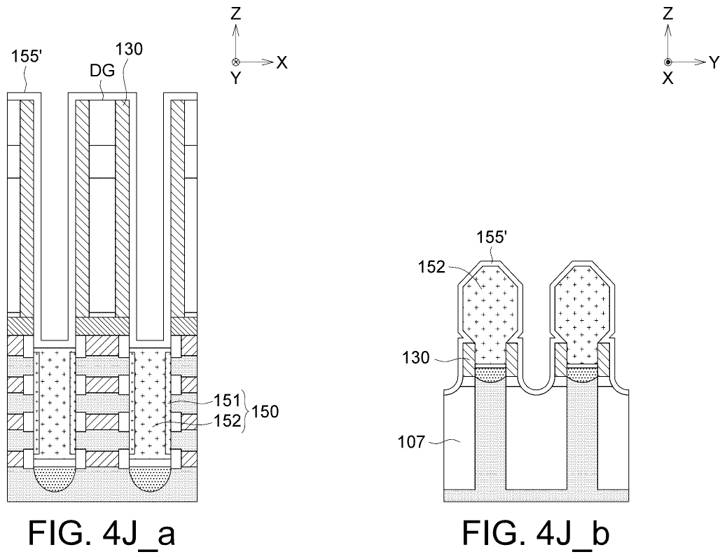

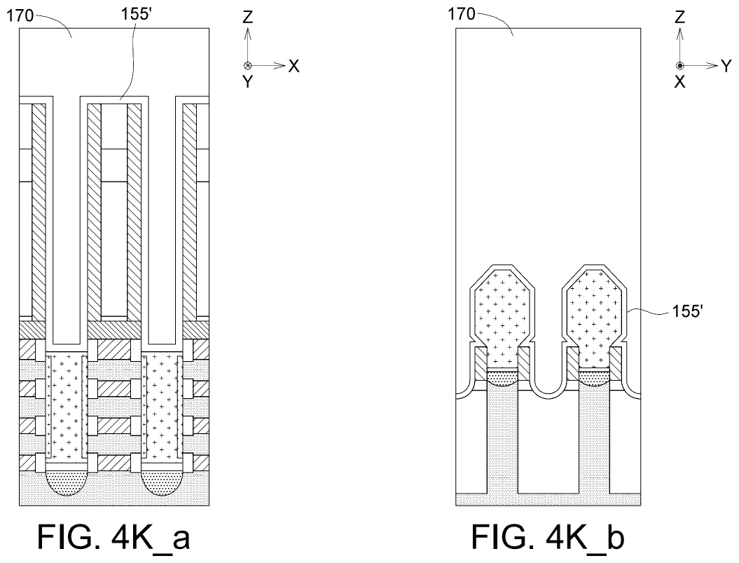

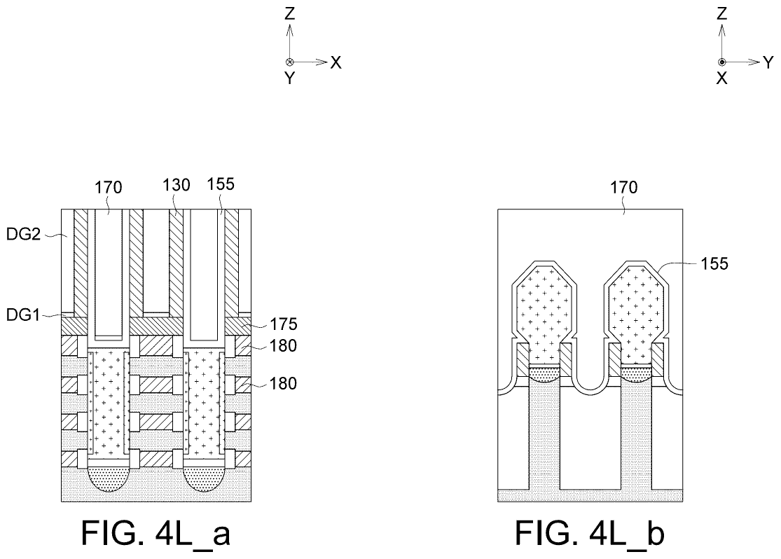

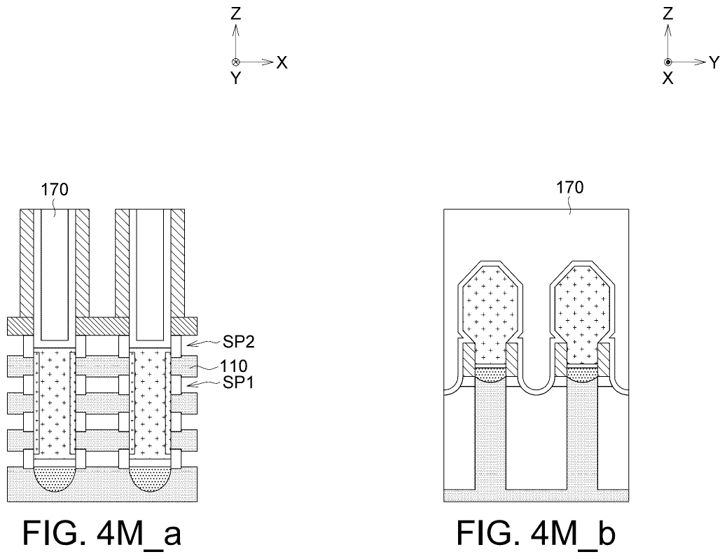

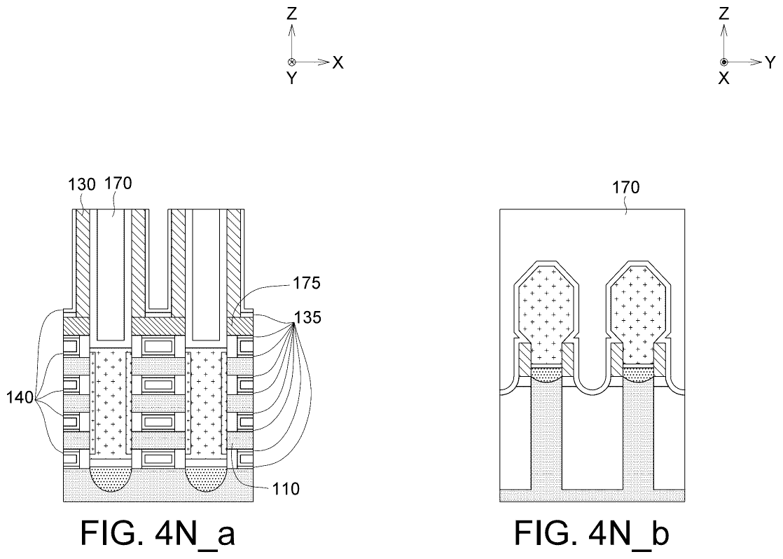

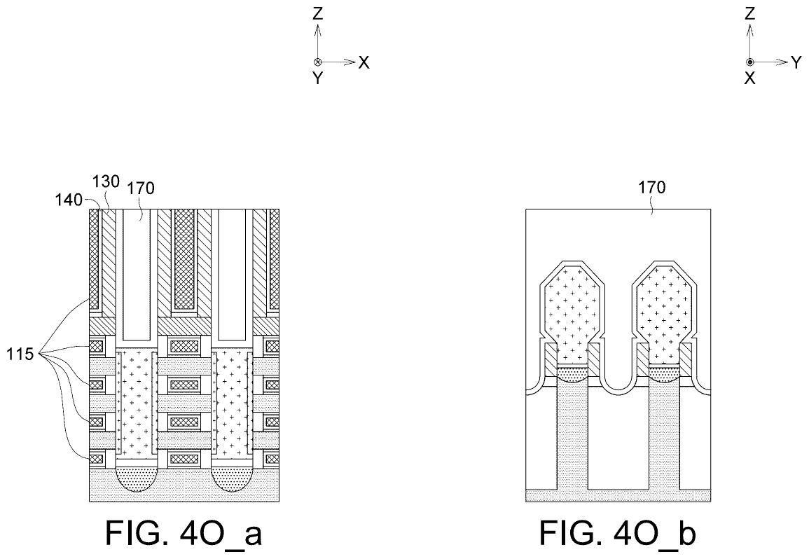

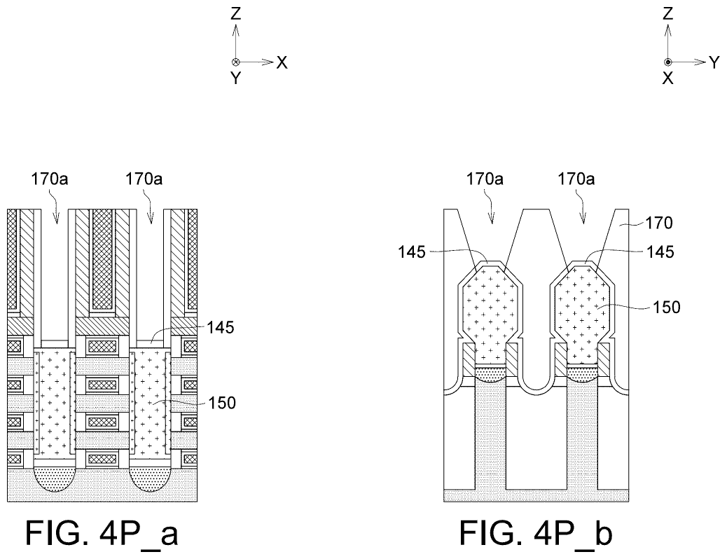

Referring to FIG. 4A_a to 4P_b, FIG. 4A_a to 4P_b illustrate schematic diagrams of manufacturing processes of the semiconductor structure 100 in FIGS. 1a to 1b.

As illustrated in FIG. 4A_a to 4A_b, a plurality of the active channel layers 110′, a plurality of SiGe layers 111′, a protection layer 110″, a protection layer 175′ are stacked on the substrate 105. Each active channel layer 110′ is formed of, for example, silicon. One of the active channel layers 110′ may be formed between adjacent two of the SiGe layers 111′. The protection layer 110″ is formed on over the topmost SiGe layer 111′, and the protection layer 175′ is formed over the protection layer 110″. The protection layer 110″ has a thickness T_{110″}, and each active channel layer 110′ has a thickness T_{110′}, wherein the thickness T_{110″} is less than the thickness T_{110′}. The protection layer 110″ may be formed of a material the same as that of the active channel layer 110′. The protection layer 110″ may protect the topmost SiGe layers 111′. In addition, the protection layer 175′ may raise the height of the gate spacer 130, and accordingly it may prevent the subsequent first source/drain portion 151 (in FIG. 4H_a) from covering the gate spacer 130 and reducing the property of the N-stressor of the first source/drain portion 151.

The dummy gate structures DG are formed on the active channels 110 by depositing, and then the gate spacer 130 is formed on adjacent two sides of the corresponding dummy gate structure DG and covers the protection layer 175′, the SiGe layers 111′, the protection layer 110″ and the active channel layers 110′. Although not illustrated, the gate spacer 130 may include the first-sub spacer portion and the second-sub spacer portion. The second-sub spacer portion is disposed between the metal gate and the first-sub spacer portion. In terms of material, the first-sub spacer portion may be formed of one of SiO, SiN, SiOC, SiON, SiOCN, etc., and the second-sub spacer portion may be formed of another of SiO, SiN, SiOC, SiON, SiOCN, etc.

The dummy gate structure DG includes a dummy dielectric layer DG1, a dummy gate layer DG2, a mask layer DG3 and an oxide layer DG4. The dummy dielectric layer DG1 is formed on the fin structures. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

As illustrated in FIG. 4A_b, the substrate 105 includes a plurality of the active regions 1051 extending in X-axis. In the present embodiment, the substrate 105 has the epitaxial crystal orientation of (110) indicated by a miller index, wherein the epitaxial crystal orientation is perpendicular to the upper surface 105u. Due to the substrate 105 with the epitaxial crystal orientation of (110) being selected, the subsequent first source/drain portion 151 (in FIG. 4H_a) may be shaped as the geometric shape as illustrated in FIG. 1a.

As illustrated in FIG. 4B_a to 4B_b, a portion of the substrate 105, a portion of the active channel layer 110′, a portion of the SiGe layer 111′, a portion of the protection layer 110″, a portion of the gate spacer 130, a portion of the protection layer 175′ and a portion of the oxide layer DG4 are removed through the dummy gate structure DG by using, for example, etching. After etching, the substrate 105 forms a plurality of the recess 105r, the remaining portion of the active channel layers 110′ forms the active channels 110, the remaining portion of the SiGe layers 111′ forms a plurality of SiGe layers 111, the remaining portion of the protection layer 110″ forms a protection layer 110″, and the remaining portion of the protection layer 175′ forms a plurality of the protection layers 175.

As illustrated in FIG. 4C_a to 4C_b, the SiGe layers 111 and the protection layers 110′″ in FIG. 4B_a are removed to expose a plurality of first spaces SP1 and a plurality of second spaces SP2 by using, for example, etching, etc., wherein each first space SP1 is located between adjacent two of the active channels 110, and the second space SP2 is located between the topmost active channel 110 and the protection layer 175.

As illustrated in FIG. 4D_a to 4D_b, an insulation material 180′ filling the first spaces SP1 and the second spaces SP2 and covering the gate spacer 130, the dummy gate structure DG, the active channels 110 and the dummy gate structures DG is formed by using, for example, deposition. In addition, the insulation material 180′ is formed of, for example, an oxide material.

As illustrated in FIG. 4E_a to 4E_b, a portion of the insulation material 180′ is removed by, for example, etching, and the remaining portion of the insulation material 180′ forms a plurality of insulation layers 180, wherein some insulation layers 180 are located within the first spaces SP1, and some insulation layers 180 are located within the second spaces SP2. After etching, a recess 180r extending to the insulation layer 180 from a lateral surface of the corresponding active channel 110 to the corresponding insulation layer 180 is formed.

As illustrated in FIG. 4F_a to 4F_b, the inner spacers 120 are formed within the recesses 180r by deposition, etching, etc. Then, the epitaxial silicon 108 may be formed within the recess 105r by, for example, epitaxial process, etc. In an embodiment, the epitaxial silicon 108 may be an undoped silicon, which means that is no dopant which is intentionally added. In another embodiment, the epitaxial silicon 108 may be replaced by an insulation material.

As illustrated in FIG. 4G_a to 4G_b, the isolation layer 125 over the epitaxial silicon 108 by using, for example, deposition, exposure, etching, development, etc. The isolation layer 125 may be configured to include a dielectric material that has, for example, aluminum (Al), titanium (Ti), lithium (Li), hafnium (Hf), zirconium (Zr), lanthanum (La), molybdenum (Mo), cobalt (Co), silicon (Si), oxygen (0), nitrogen (N), carbon (C), any other suitable elements, or combinations thereof. In some embodiments, the isolation layer 125 may include a low-k dielectric material having a k parameter less than about 3.9. As described later, the isolation layer 125 separates two adjacent source/drain features, and having a low k parameter improves the isolation therebetween. In some embodiments, the isolation layer 125 may be silicon nitride, silicon carbonitride, silicon oxynitride, silicon carboxynitride, or combinations thereof. Any suitable methods may be used to form the isolation layer 125. In the depicted embodiments, the isolation layer 125 is formed using ALD, CVD, PVD, other suitable methods, or combinations thereof.

As illustrated in FIG. 4H_a to 4H_b, the first source/drain portion 151 is formed by using, for example, epitaxial process, such as VPE, UHV-CVD, MBE, and/or other suitable processes. In terms of material, the first source/drain portion 151 may be formed of, for example, SiGe (Silicon-germanium), SiGeAs or SiGeP. In the present embodiment, the first source/drain portion 151 is a single and contiguous layer, for example. Furthermore, the first source/drain portion 151 may extend contiguously from the topmost active channel 110 to the bottommost active channel 110. In an embodiment, the first source/drain portion 151 may protrude relative to an upper surface 110u of the topmost active channel 110, and protrude relative to a lower surface 110b of the bottommost active channel 110. In addition, each inner spacer 120 has the lateral surface 120s, wherein the first source/drain portion 151 covers at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120. In the present embodiment, the first source/drain portion 151 may be in contact with at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120.

In addition, the first source/drain portion 151 has the upper surface 151u, and the upper surface 151u is substantially parallel to the OD direction (for example, X-axis). In addition, the first source/drain portion 151 has the lateral surface 151s, wherein the minimum included angle A1 between the tangential of any point P1 (for example, the connection point between the upper surface 151u and the lateral surface 151s) of the lateral surface 151s and a horizontal axis (for example, X-axis) may be equal to or greater than 60 degrees, 70 degrees, 80 degrees, 90 degrees, or a real number ranging 60 degrees and 90 degrees. Due to the substrate 105 with the epitaxial crystal orientation of (110) being selected, the first source/drain portion 151 may be shaped as the geometric shape as illustrated in FIG. 4H_a. In the present embodiment, the first source/drain portion 151 is formed of high resistance material (its property tends to P-type semiconductor material), and thus it is not good for the electron mobility of the N-type transistor. However, the size ratio of the first source/drain portion 151 may apply a greater tensile stress to the active channels 110, and thus it is conducive to the electron mobility of the N-type transistor.

As illustrated in FIG. 4I_a to 4I_b, the second source/drain portion 152 covering the first source/drain portions 151, a portion of the inner spacers 120 and the isolation layers 125 is formed by using, for example, epitaxial process. The source/drain layer 150 including the first source/drain portion 151 and the second source/drain portion 152 is formed in the epitaxial process. In terms of material, the second source/drain portion 152 may be formed of, for example, SiAs or SiP. Due to the substrate 105 with the epitaxial crystal orientation of (110) being selected, the second source/drain portion 152 may form a specific degrees. Furthermore, the second source/drain portion 152 has the upper surface 152u, the lateral surface 152s1 and the inclined surface 152s2, wherein the inclined surface 152s2 connects the upper surface 152u with the lateral surface 152s1, and the included angle A2 between the upper surface 152u and the inclined surface 152s2 may be less than 40 degrees, for example, 35.3 degrees.

As illustrated in FIG. 4J_a to 4J_b, a CESL material 155′ over the gate spacers 130, the second source/drain portions 152 of the source/drain layers 150, and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like.

As illustrated in FIG. 4K_a to 4K_b, the ILD 170 covering the CESL material 155′ is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

As illustrated in FIG. 4L_a to 4L_b, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layers DG, the gate spacers 130 and the ILD 170 may form, for example, a planarized surface.

As illustrated in FIG. 4M_a to 4M_b, the insulation layers 180 and the dummy dielectric layer DG1 and the dummy gate layer DG2 of the dummy gate structure DG in FIG. 4L_a may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the insulation layers 180 also be removed by using, for example, etching. After the dummy gate structures DG and the insulation layers 180 are removed, the active channels 110, the first spaces SP1 and the second spaces SP2 are exposed.

As illustrated in FIG. 4N_a to 4N_b, the first dielectric layers 135 on the active channels 110 and the protection layers 175 are formed by using, for example, deposition. Then, the second dielectric layer 140 over or on the inner spacers 120 and the first dielectric layers 135 are formed by using, for example, deposition.

As illustrated in FIG. 4O_a to 4O_b, the metal gate 115 on the second dielectric layer 140 is formed by a process such as ALD, CVD, PVD, remote plasma CVD (RPCVD), plasma enhanced CVD (PECVD), metal-organic CVD (MOCVD), sputtering, electroplating, other suitable processes, or the like. Then, a CMP may be conducted to planarize the second dielectric layer 140, the gate spacers 130, the ILD 170 and the metal gate 115.

The metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

As illustrated in FIG. 4P_a to 4P_b, a portion of the ILD 170 and a bottom portion of the CESL 155 in FIG. 4O_a are removed to form at least hole 170a to expose the source/drain layers 150 by using, for example, deposition, photolithography, etching, etc. Then, the silicide layers 145 on the exposed source/drain layers 150 are formed by using, for example, deposition.

Then, the contacts 160 (as illustrated in FIGS. 1a and 1a) are formed on the source/drain layers 150 (as illustrated in FIG. 4P_a to 4P_b) through the holes 170a to form at least one semiconductor structure 100 as illustrated in FIGS. 1a and 1b. The contacts 160 may be formed of a metal including the material the same as or similar to that of the metal gate 115, for example.

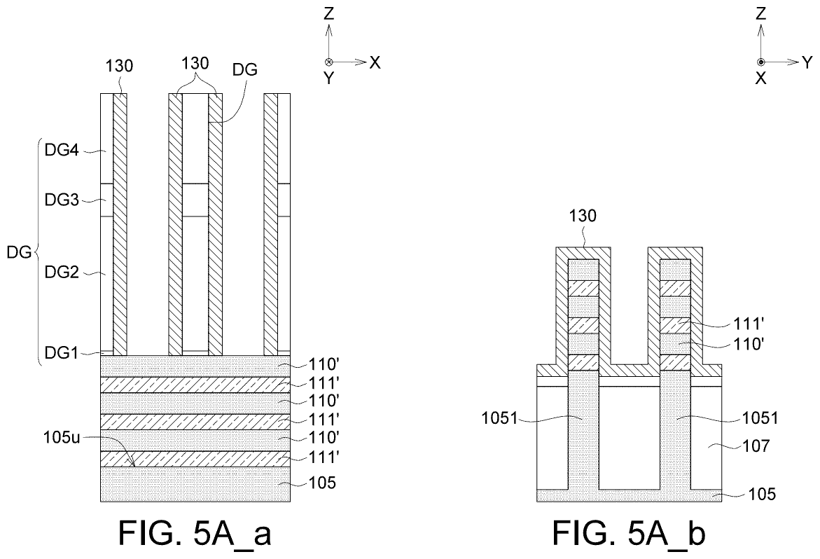

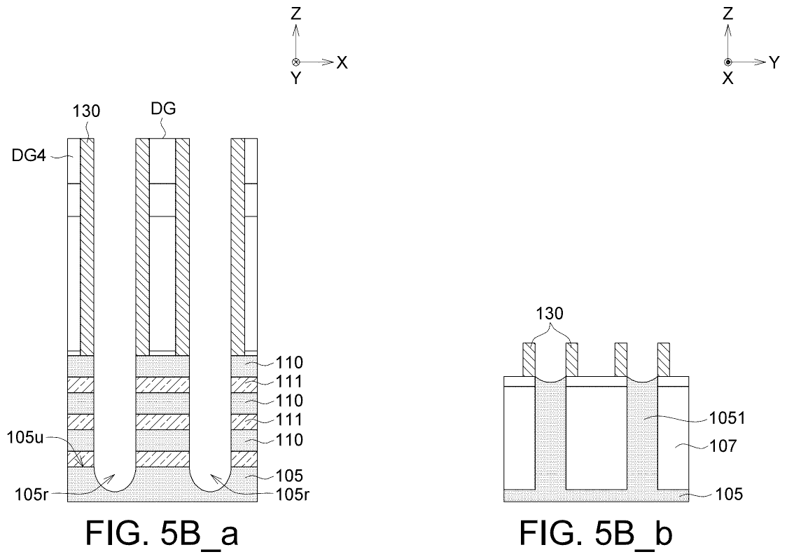

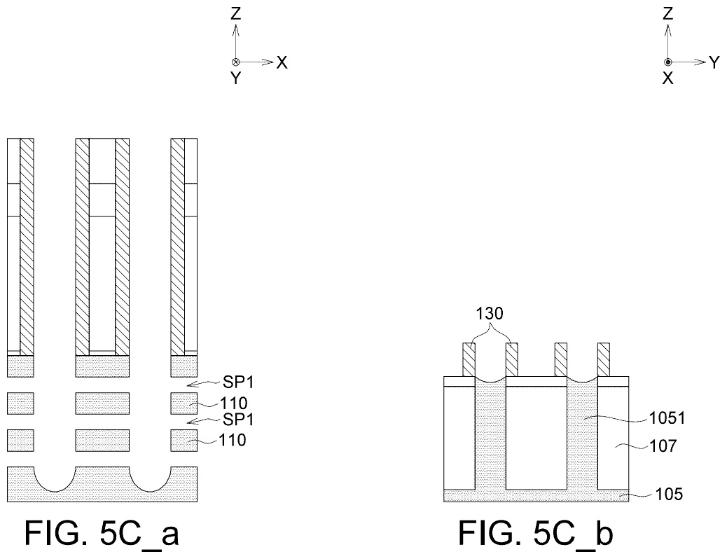

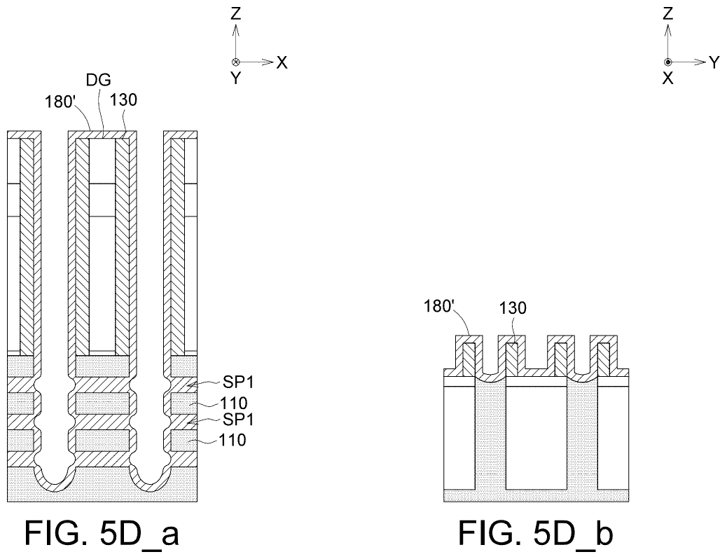

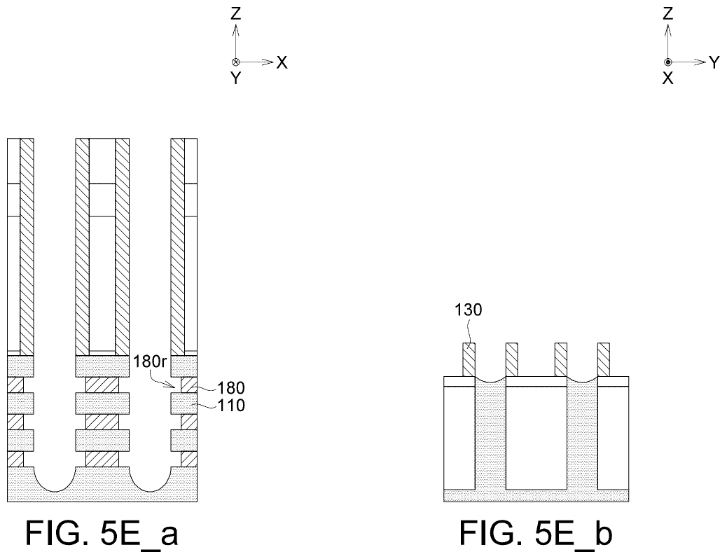

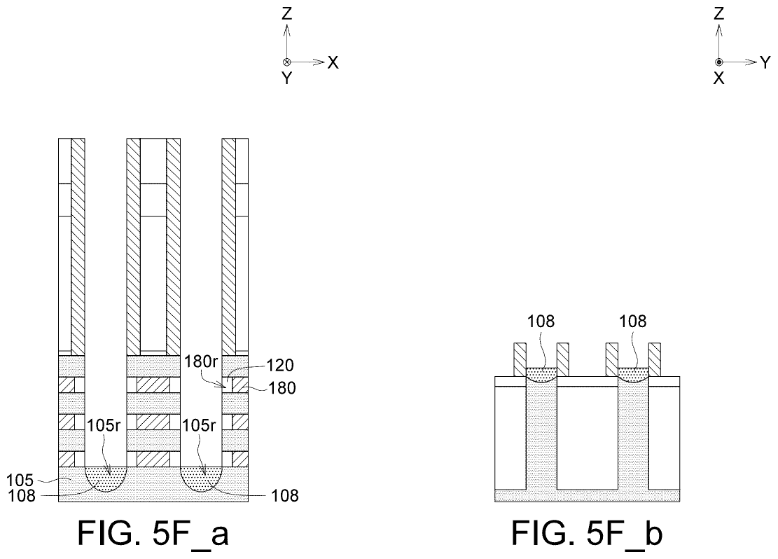

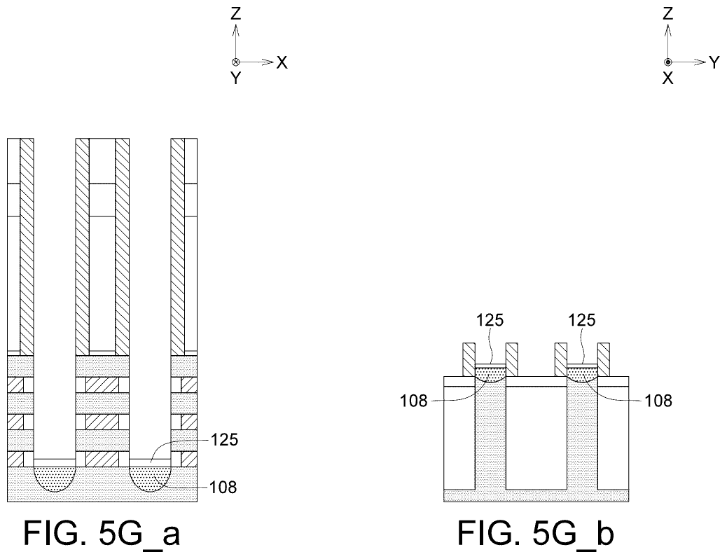

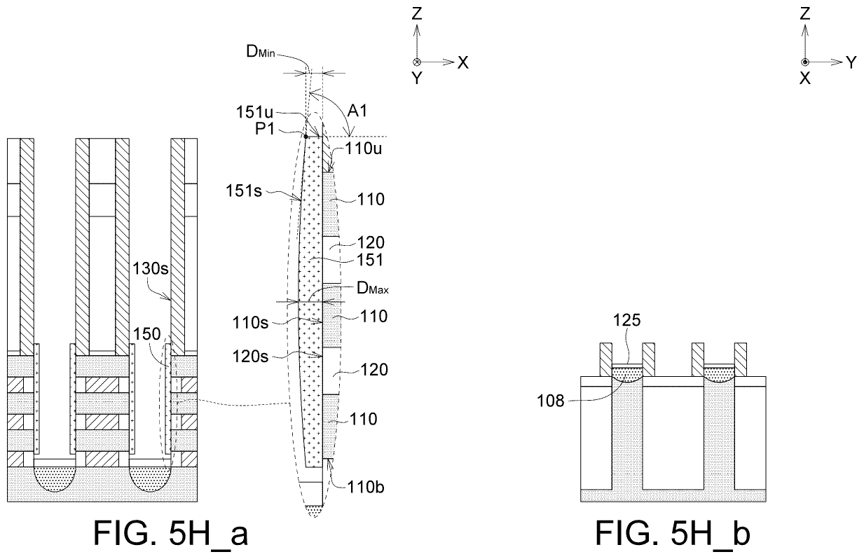

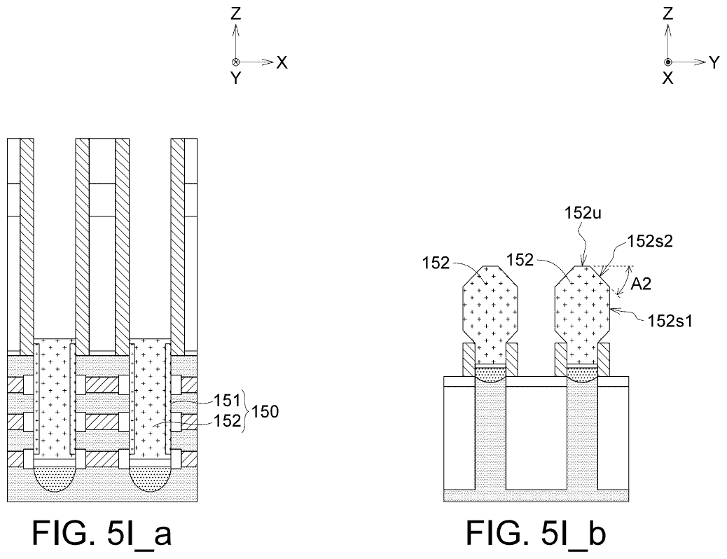

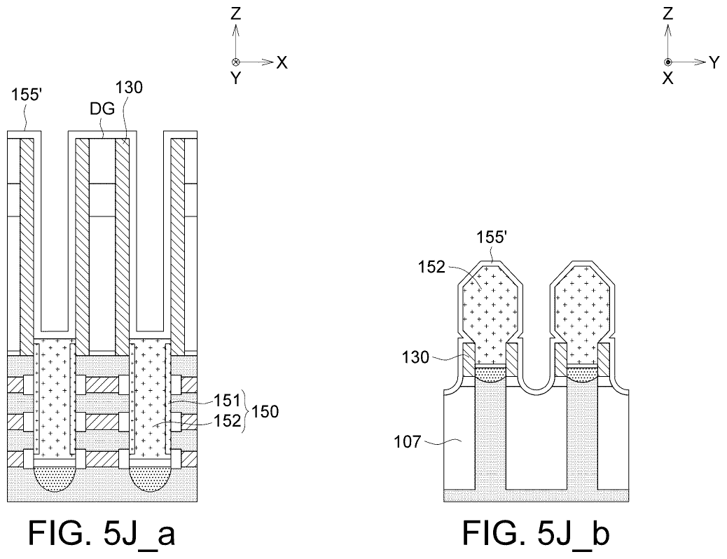

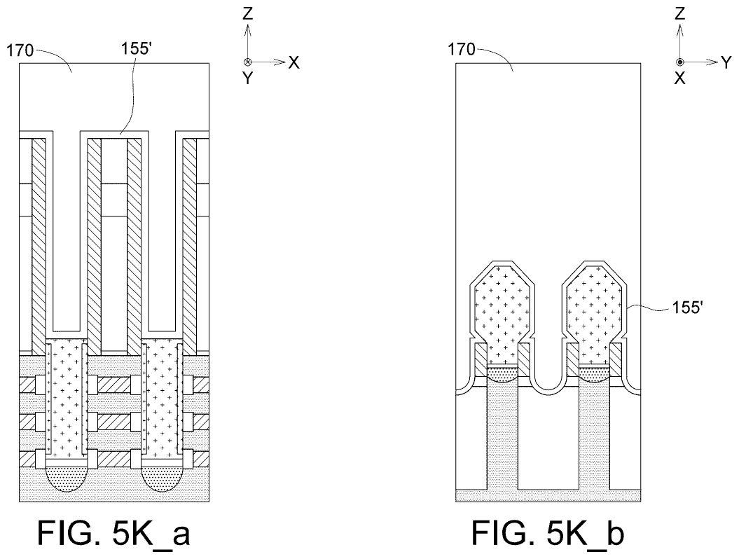

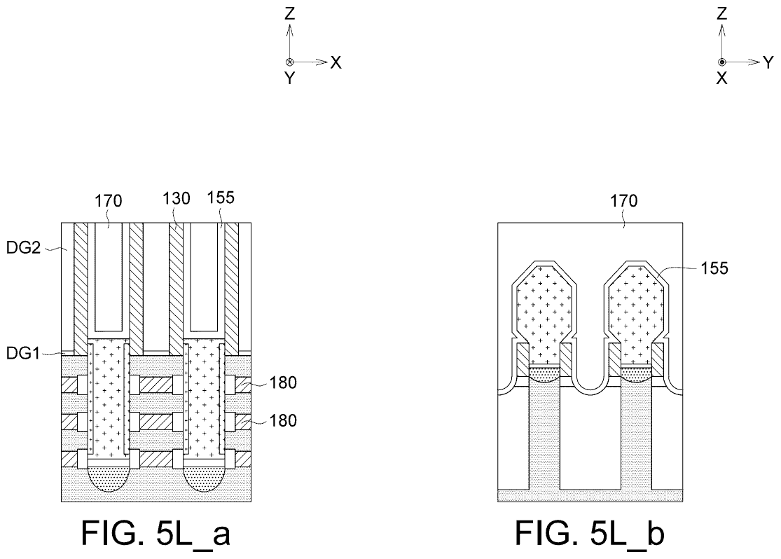

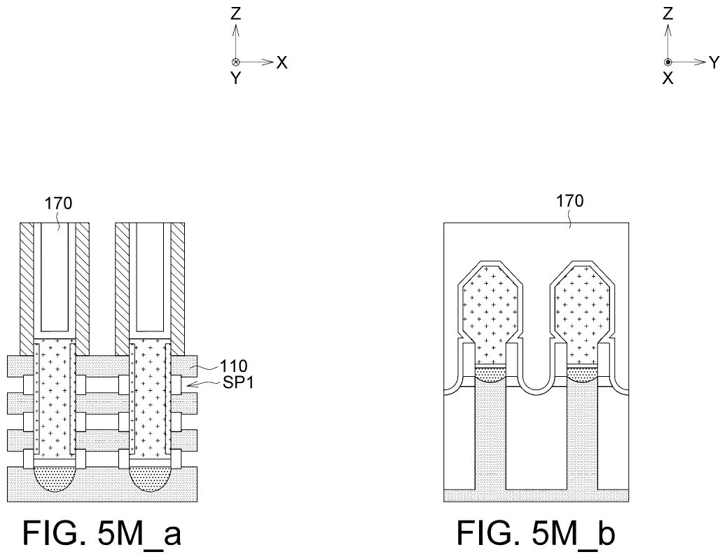

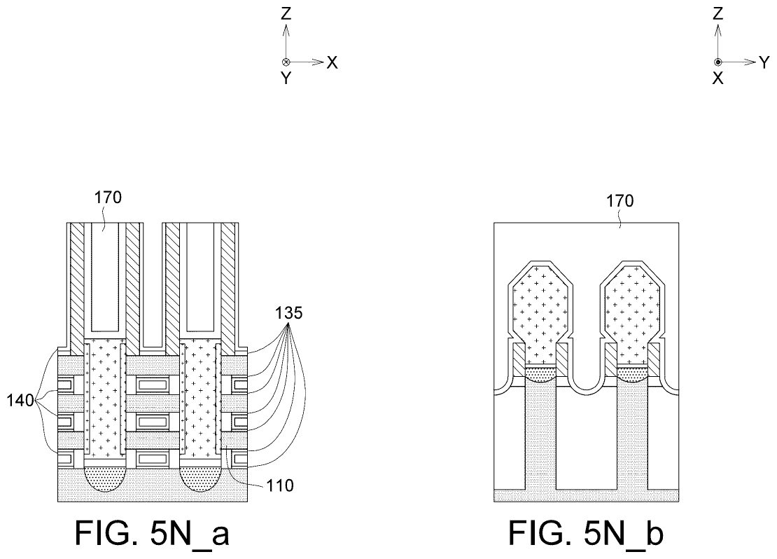

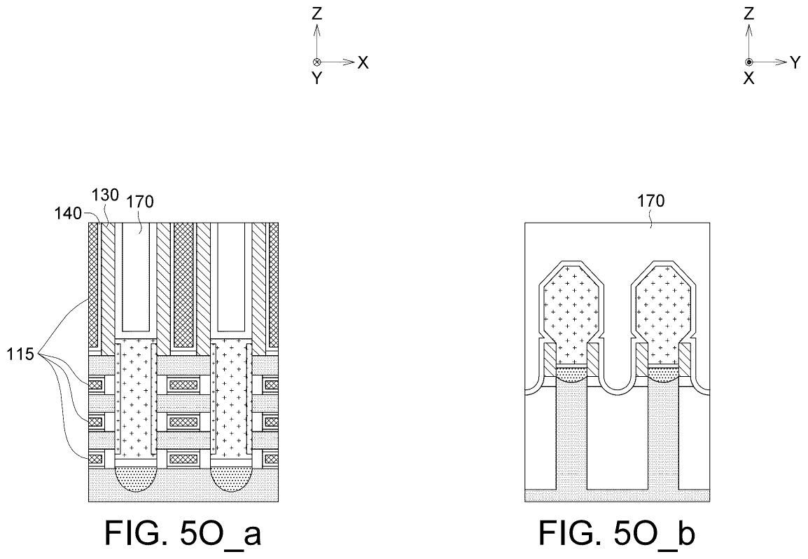

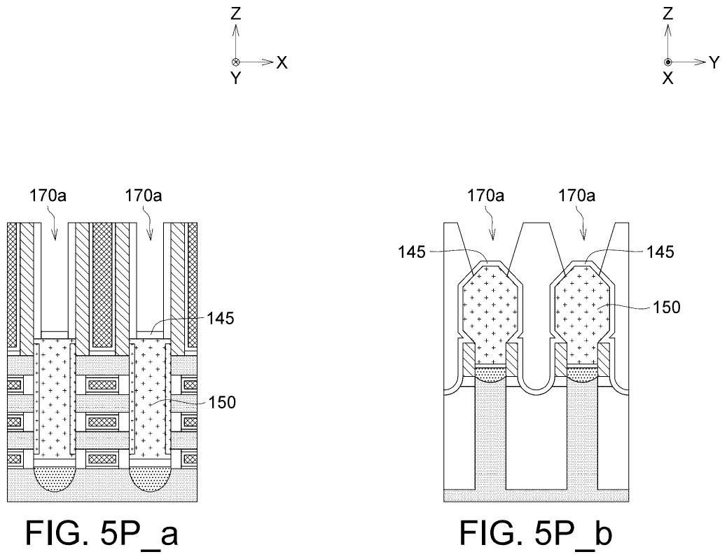

Referring to FIG. 5A_a to 5P_b, FIG. 5A_a to 5P_b illustrate schematic diagrams of manufacturing processes of the semiconductor structure 200 in FIGS. 2a to 2b.

As illustrated in FIG. 5A_a to 5A_b, a plurality of the active channel layers 110′ and a plurality of SiGe layers 111′ are stacked on the substrate 105. Each active channel layer 110′ is formed of, for example, silicon. One of the active channel layers 110′ may be formed between adjacent two of the SiGe layers 111′.

The dummy gate structures DG are formed on the active channels 110 by depositing, and then the gate spacer 130 is formed on adjacent two sides of the corresponding dummy gate structure DG and covers the SiGe layers 111′ and the active channel layers 110′. Although not illustrated, the gate spacer 130 may include the first-sub spacer portion and the second-sub spacer portion. The second-sub spacer portion is disposed between the metal gate and the first-sub spacer portion. In terms of material, the first-sub spacer portion may be formed of one of SiO, SiN, SiOC, SiON, SiOCN, etc., the second-sub spacer portion may be formed of another of SiO, SiN, SiOC, SiON, SiOCN, etc.

The dummy gate structure DG includes a dummy dielectric layer DG1, a dummy gate layer DG2, a mask layer DG3 and an oxide layer DG4. The dummy dielectric layer DG1 is formed on the fin structures. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

As illustrated in FIG. 5A_b, the substrate 105 includes a plurality of the active regions 1051 extending in X-axis. In the present embodiment, the substrate 105 has the epitaxial crystal orientation of (110) indicated by a miller index, wherein the epitaxial crystal orientation is perpendicular to the upper surface 105u. Due to the substrate 105 with the epitaxial crystal orientation of (110) being selected, the subsequent first source/drain portion 151 (in FIG. 5H_a) may be shaped as the geometric shape as illustrated in FIG. 1a.

As illustrated in FIG. 5B_a to 5B_b, a portion of the substrate 105, a portion of the active channel layer 110′, a portion of the SiGe layer 111′, a portion of the gate spacer 130 and a portion of the oxide layer DG4 are removed through the dummy gate structure DG by using, for example, etching. After etching, the substrate 105 forms a plurality of the recess 105r, the remaining portion of the active channel layers 110′ forms the active channels 110, and the remaining portion of the SiGe layers 111′ forms a plurality of the SiGe layers 111.

As illustrated in FIG. 5C_a to 5C_b, the SiGe layers 111 in FIG. 5B_a are removed to expose a plurality of the first spaces SP1 by using, for example, etching, etc., wherein each first space SP1 is located between adjacent two of the active channels 110.

As illustrated in FIG. 5D_a to 5D_b, the insulation material 180′ filling the first spaces SP1 and covering the gate spacer 130, the dummy gate structure DG, the active channels 110 and the dummy gate structures DG is formed by using, for example, deposition. In addition, the insulation material 180′ is formed of, for example, an oxide material.

As illustrated in FIG. 5E_a to 5E_b, a portion of the insulation material 180′ is removed by, for example, etching, and the remaining portion of the insulation material 180′ forms a plurality of insulation layers 180, wherein the insulation layers 180 are located within the first spaces SP1. After etching, the recess 180r extending to the insulation layer 180 from the lateral surface of the corresponding active channel 110 to the corresponding insulation layer 180 is formed.

As illustrated in FIG. 5F_a to 5F_b, the inner spacers 120 are formed within the recesses 180r by deposition, etching, etc. Then, the epitaxial silicon 108 may be formed within the recess 105r by, for example, epitaxial process, etc.

As illustrated in FIG. 5G_a to 5G_b, the isolation layer 125 over the epitaxial silicon 108 by using, for example, deposition, exposure, etching, development, etc. The isolation layer 125 may be configured to include a dielectric material that has, for example, aluminum (Al), titanium (Ti), lithium (Li), hafnium (Hf), zirconium (Zr), lanthanum (La), molybdenum (Mo), cobalt (Co), silicon (Si), oxygen (0), nitrogen (N), carbon (C), any other suitable elements, or combinations thereof. In some embodiments, the isolation layer 125 may include a low-k dielectric material having a k parameter less than about 3.9. As described later, the isolation layer 125 separates two adjacent source/drain features, and having a low k parameter improves the isolation therebetween. In some embodiments, the isolation layer 125 may be silicon nitride, silicon carbonitride, silicon oxynitride, silicon carboxynitride, or combinations thereof. Any suitable methods may be used to form the isolation layer 125. In the depicted embodiments, the isolation layer 125 is formed using ALD, CVD, PVD, other suitable methods, or combinations thereof.

As illustrated in FIG. 5H_a to 5H_b, the first source/drain portion 151 is formed by using, for example, epitaxial process, such as VPE, UHV-CVD, MBE, and/or other suitable processes. In terms of material, the first source/drain portion 151 may be formed of, for example, SiGe (Silicon-germanium), SiGeAs or SiGeP. In the present embodiment, the first source/drain portion 151 is a single and contiguous layer, for example. Furthermore, the first source/drain portion 151 may extend contiguously from the topmost active channel 110 to the bottommost active channel 110. In an embodiment, the first source/drain portion 151 may protrude relative to an upper surface 110u of the topmost active channel 110, and protrude relative to a lower surface 110b of the bottommost active channel 110. In addition, each inner spacer 120 has the lateral surface 120s, wherein the first source/drain portion 151 covers at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120. In the present embodiment, the first source/drain portion 151 may be in contact with at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120.

In the present embodiment, the first source/drain portion 151 may extend to a portion of the lateral surface 130s of the corresponding gate spacer 130 due to omitting the protection layers 175 in FIG. 1a.

In addition, the first source/drain portion 151 has the upper surface 151u, and the upper surface 151u is substantially parallel to the OD direction (for example, X-axis). In addition, the first source/drain portion 151 has the lateral surface 151s, wherein the minimum included angle A1 between the tangential of any point P1 (for example, the connection point between the upper surface 151u and the lateral surface 151s) of the lateral surface 151s and a horizontal axis (for example, X-axis) may be equal to or greater than 60 degrees, 70 degrees, 80 degrees, 90 degrees, or a real number ranging 60 degrees and 90 degrees. Due to the substrate 105 with the epitaxial crystal orientation of (110) being selected, the first source/drain portion 151 may be shaped as the geometric shape as illustrated in FIG. 5H_a. In the present embodiment, the first source/drain portion 151 is formed of high resistance material (its property tends to P-type semiconductor material), and thus it is not good for the electron mobility of the N-type transistor. However, the size ratio of the first source/drain portion 151 may apply a greater tensile stress to the active channels 110, and thus it is conducive to the electron mobility of the N-type transistor.

As illustrated in FIG. 5I_a to 5I_b, the second source/drain portion 152 covering the first source/drain portions 151, a portion of the inner spacers 120 and the isolation layers 125 is formed by using, for example, epitaxial process. The source/drain layer 150 including the first source/drain portion 151 and the second source/drain portion 152 is formed in the epitaxial process. In terms of material, the second source/drain portion 152 may be formed of, for example, SiAs or SiP. Due to the substrate 105 with the epitaxial crystal orientation of (110) being selected, the second source/drain portion 152 may form a specific degrees. Furthermore, the second source/drain portion 152 has the upper surface 152u, the lateral surface 152s1 and the inclined surface 152s2, wherein the inclined surface 152s2 connects the upper surface 152u with the lateral surface 152s1, and the included angle A2 between the upper surface 152u and the inclined surface 152s2 may be less than 40 degrees, for example, 35.3 degrees.

As illustrated in FIG. 5J_a to 5J_b, the CESL material 155′ over the gate spacers 130, the second source/drain portions 152 of the source/drain layers 150, and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like.

As illustrated in FIG. 5K_a to 5K_b, the ILD 170 covering the CESL material 155′ is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

As illustrated in FIG. 5L_a to 5L_b, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layers DG, the gate spacers 130 and the ILD 170 may form, for example, a planarized surface.

As illustrated in FIG. 5M_a to 5M_b, the insulation layers 180 and the dummy dielectric layer DG1 and the dummy gate layer DG2 of the dummy gate structure DG in FIG. 5L_a may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the insulation layers 180 also be removed by using, for example, etching. After the dummy gate structures DG and the insulation layers 180 are removed, the active channels 110, the first spaces SP1 and the second spaces SP2 are exposed.

As illustrated in FIG. 5N_a to 5N_b, the first dielectric layers 135 on the active channels 110 are formed by using, for example, deposition. Then, the second dielectric layer 140 over or on the inner spacers 120 and the first dielectric layers 135 are formed by using, for example, deposition.

As illustrated in FIG. 5O_a to 5O_b, the metal gate 115 on the second dielectric layer 140 is formed by a process such as ALD, CVD, PVD, remote plasma CVD (RPCVD), plasma enhanced CVD (PECVD), metal-organic CVD (MOCVD), sputtering, electroplating, other suitable processes, or the like. Then, a CMP may be conducted to planarize the second dielectric layer 140, the gate spacers 130, the ILD 170 and the metal gate 115.

The metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

As illustrated in FIG. 5P_a to 5P_b, a portion of the ILD 170 and a bottom portion of the CESL 155 in FIG. 5O_a are removed to form at least hole 170a to expose the source/drain layers 150 by using, for example, deposition, photolithography, etching, etc. Then, the silicide layers 145 on the exposed source/drain layers 150 are formed by using, for example, deposition.

Then, the contacts 160 (as illustrated in FIGS. 2a and 2a) are formed on the source/drain layers 150 (as illustrated in FIG. 5P_a to 5P_b) through the holes 170a to form at least one semiconductor structure 200 as illustrated in FIGS. 2a and 2b. The contacts 160 may be formed of a metal including the material the same as or similar to that of the metal gate 115, for example.

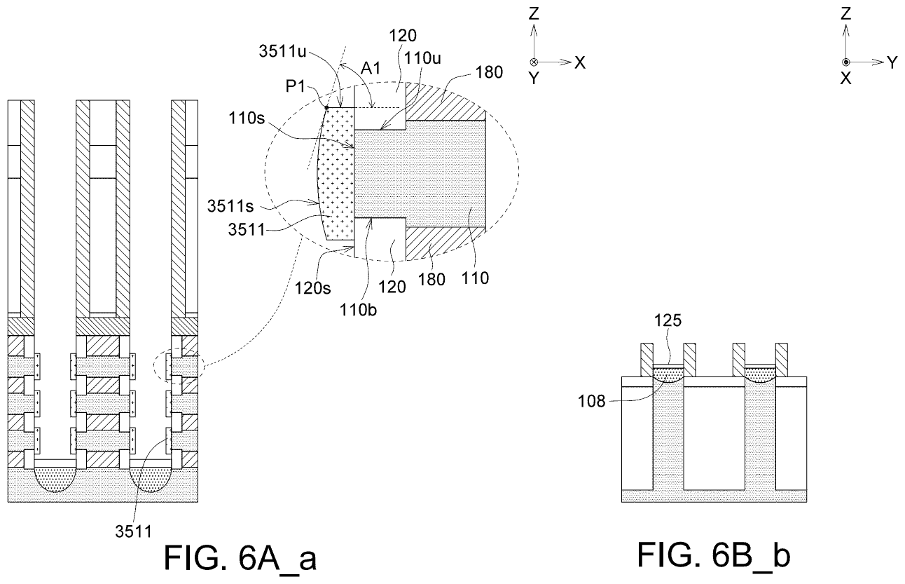

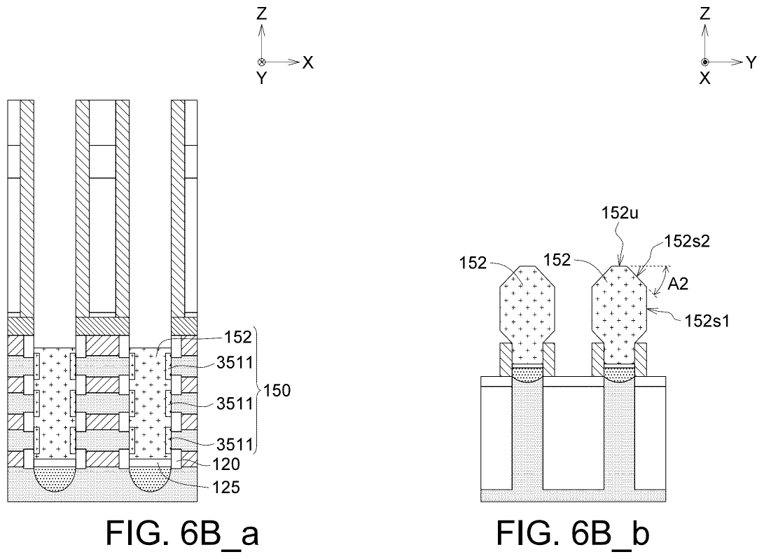

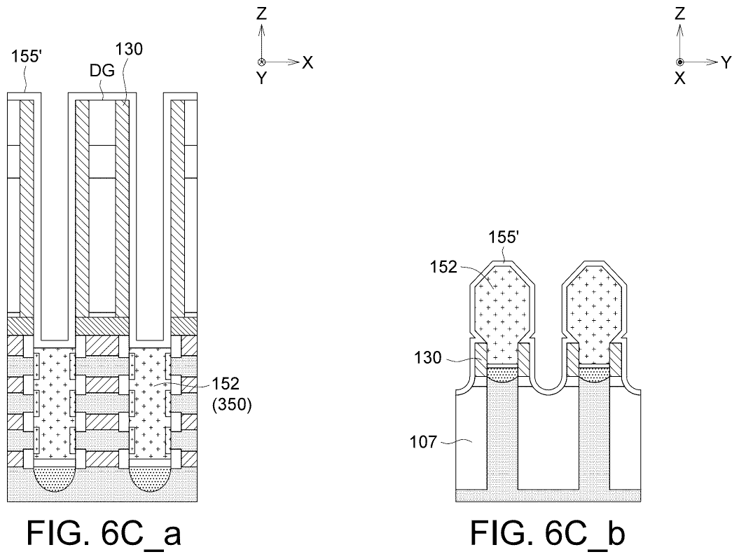

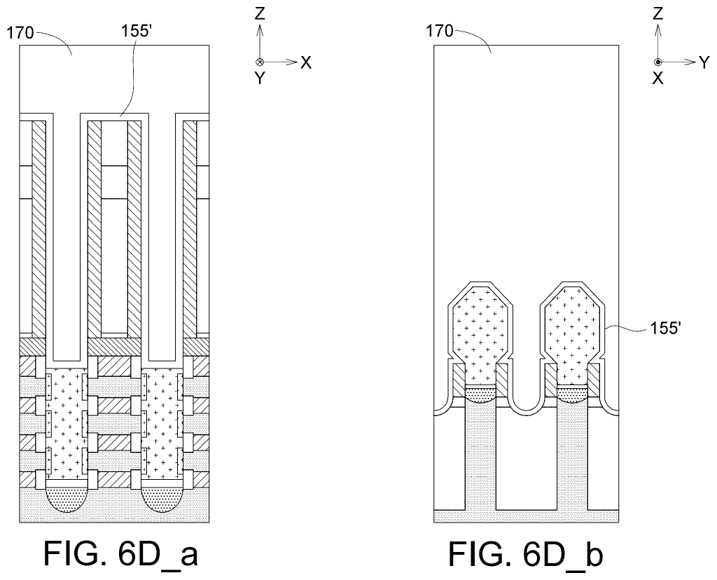

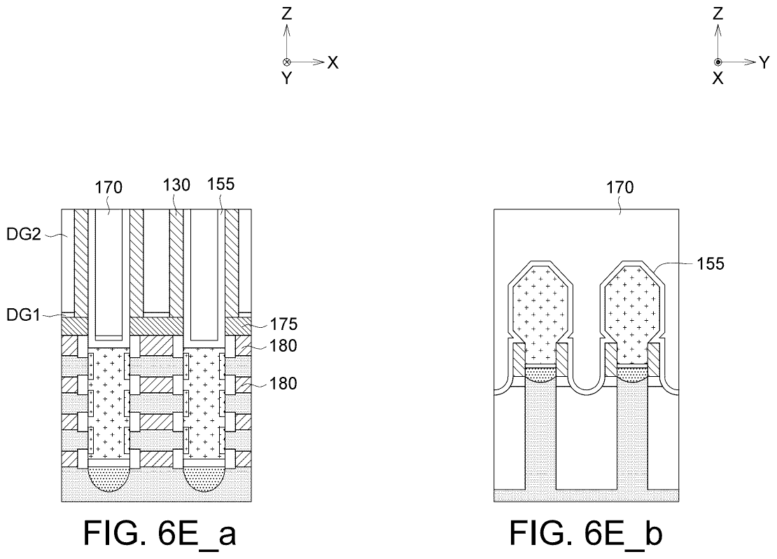

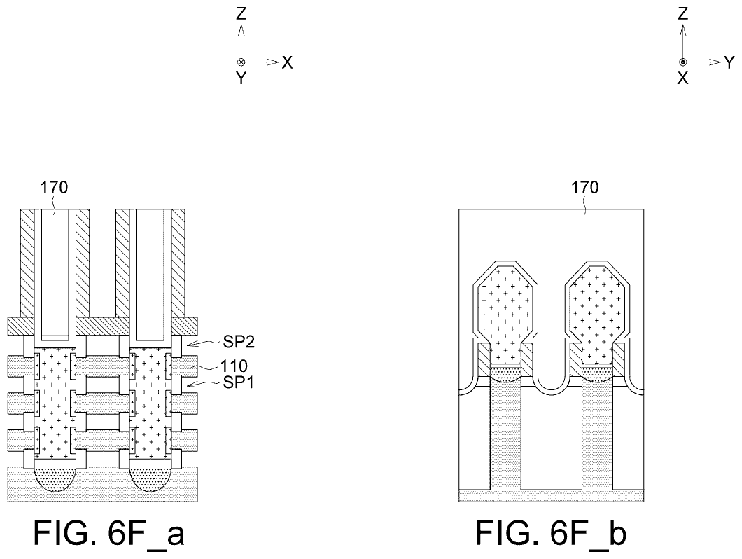

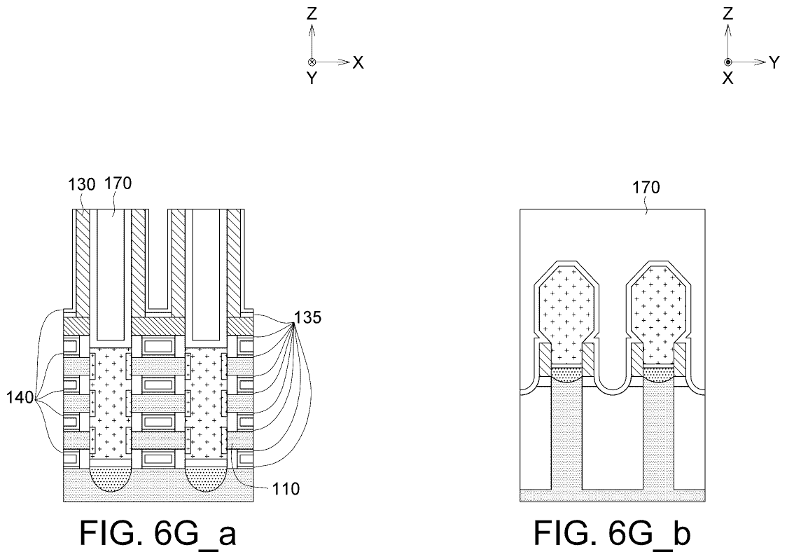

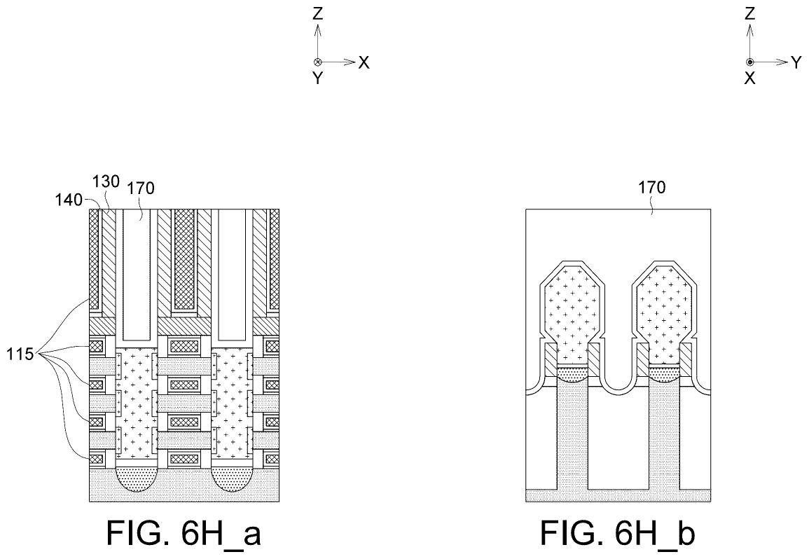

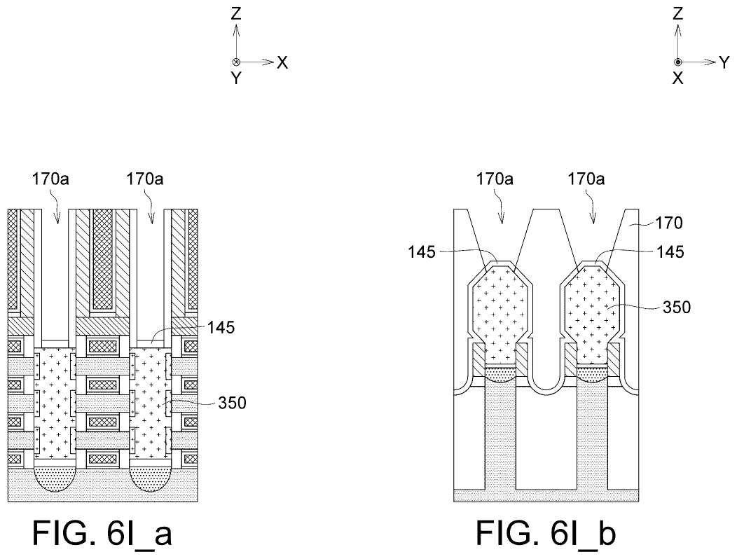

Referring to FIG. 6A_a to 6I_b, FIG. 6A_a to 6I_b illustrate schematic diagrams of manufacturing processes of the semiconductor structure 300 in FIGS. 3a to 3b. The manufacturing processes of the semiconductor structure 300 include the steps the same as or similar to that in FIG. 4A_a and 4A_b to FIG. 4G_a and 4G_b, and they will not repeated here. The manufacturing processes of the semiconductor structure 300 are explained starting from the step of the isolation layer 125 over the epitaxial silicon 108 being formed.

As illustrated in FIG. 6A_a and 6B_b, the first source/drain portion 351 is formed by using, for example, epitaxial process, such as VPE, UHV-CVD, MBE, and/or other suitable processes. In terms of material, the first source/drain portion 351 may be formed of, for example, SiGe (Silicon-germanium), SiGeAs or SiGeP. In the present embodiment, the first source/drain portion 351 includes a plurality of the sub-source/drain portions 3511, wherein the sub-source/drain portions 3511 are separated from each other. Each sub-source/drain portion 3511 is disposed on the entirety of the lateral surface 110s of the corresponding the active channel 110 and a portion of the lateral surface 120s of the corresponding inner spacer 120.

The sub-source/drain portion 3511 covers the lateral surfaces 110s of the active channel 110. The sub-source/drain portion 3511 has the maximum outer diameter (or maximum outer size) D_{Max} (for example, in X-axis) and the minimum outer diameter (or minimum outer size) D_{Min} (for example, in X-axis), and a ratio of the maximum outer diameter D_{Max} to the minimum outer diameter D_{Min} may be less than 1.1, or even greater or less.

In the present embodiment, the first source/drain portion 351 is formed of high resistance material (its property tends to P-type semiconductor material), and thus it is not good for the electron mobility of the N-type transistor. However, the size ratio of the first source/drain portion 351 may apply a greater tensile stress to the active channels 110, and thus it is conducive to the electron mobility of the N-type transistor. The first source/drain portion 351 may be formed of a material the same as or similar to that of the first source/drain portion 151.

Each sub-source/drain portion 3511 may protrude relative to the upper surface 110u of the corresponding active channel 110, and protrude relative to the lower surface 110b of the corresponding active channel 110. In addition, each inner spacer 120 has the lateral surface 120s, wherein each sub-source/drain portion 3511 covers at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120. In the present embodiment, each sub-source/drain portion 3511 may be in contact with at least a portion of the lateral surface 110s of each of at least one of the active channels 110, or covers at least a portion of the lateral surface 110s of each of at least one of the active channels 110 and at least a portion of the lateral surface 120s of each of at least one of the inner spacers 120.

In addition, each sub-source/drain portion 3511 has the upper surface 3511u, and the upper surface 3511u is substantially parallel to the OD direction (for example, X-axis). In addition, each sub-source/drain portion 3511 has the lateral surface 3511s, wherein the minimum included angle A1 between the tangential of any point P1 (for example, the connection point between the upper surface 3511u and the lateral surface 3511s) of the lateral surface 3511s and a horizontal axis (for example, X-axis) may be equal to or greater than 60 degrees, 70 degrees, 80 degrees, 90 degrees, or a real number ranging 60 degrees and 90 degrees.

As illustrated in FIG. 6B_a and 6B_b, the second source/drain portion 152 covering the first source/drain portions 351, a portion of the inner spacers 120 and the isolation layers 125 is formed by using, for example, epitaxial process. The source/drain layer 350 including the first source/drain portion 351 and the second source/drain portion 152 is formed in the epitaxial process. In terms of material, the second source/drain portion 152 may be formed of, for example, SiAs or SiP. Due to the substrate 105 with the epitaxial crystal orientation of (110) being selected, the second source/drain portion 152 may form a specific degrees. Furthermore, the second source/drain portion 152 has the upper surface 152u, the lateral surface 152s1 and the inclined surface 152s2, wherein the inclined surface 152s2 connects the upper surface 152u with the lateral surface 152s1, and the included angle A2 between the upper surface 152u and the inclined surface 152s2 may be less than 40 degrees, for example, 35.3 degrees.

As illustrated in FIG. 6C_a to 6C_b, the CESL material 155′ over the gate spacers 130, the second source/drain portions 152 of the source/drain layers 350, and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like.

As illustrated in FIG. 6D_a to 6D_b, the ILD 170 covering the CESL material 155′ is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

As illustrated in FIG. 6E_a to 6E_b, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layers DG, the gate spacers 130 and the ILD 170 may form, for example, a planarized surface.

As illustrated in FIG. 6F_a to 6F_b, the insulation layers 180 and the dummy dielectric layer DG1 and the dummy gate layer DG2 of the dummy gate structure DG in FIG. 6E_a may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the insulation layers 180 also be removed by using, for example, etching. After the dummy gate structures DG and the insulation layers 180 are removed, the active channels 110, the first spaces SP1 and the second spaces SP2 are exposed.

As illustrated in FIG. 6G_a to 6G_b, the first dielectric layers 135 on the active channels 110 are formed by using, for example, deposition. Then, the second dielectric layer 140 over or on the inner spacers 120 and the first dielectric layers 135 are formed by using, for example, deposition.

As illustrated in FIG. 6H_a to 6H_b, the metal gate 115 on the second dielectric layer 140 is formed by a process such as ALD, CVD, PVD, remote plasma CVD (RPCVD), plasma enhanced CVD (PECVD), metal-organic CVD (MOCVD), sputtering, electroplating, other suitable processes, or the like. Then, a CMP may be conducted to planarize the second dielectric layer 140, the gate spacers 130, the ILD 170 and the metal gate 115.

The metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

As illustrated in FIG. 6I_a to 6I_b, a portion of the ILD 170 and a bottom portion of the CESL 155 in FIG. 5O_a are removed to form at least hole 170a to expose the source/drain layers 150 by using, for example, deposition, photolithography, etching, etc. Then, the silicide layers 145 on the exposed source/drain layers 150 are formed by using, for example, deposition.

Then, the contacts 160 (as illustrated in FIGS. 3a and 3a) are formed on the source/drain layers 150 (as illustrated in FIG. 6I_a to 6I_b) through the holes 170a to form at least one semiconductor structure 300 as illustrated in FIGS. 3a and 3b. The contacts 160 may be formed of a metal including the material the same as or similar to that of the metal gate 115, for example.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a substrate, a plurality of active channels and a source/drain layer. The plurality of active channels are disposed on the substrate and vertically stacked to each other, wherein each active channel has a lateral surface. The source/drain layer covers the lateral surfaces of the active channels and has a maximum outer size and a minimum outer size, wherein a ratio of the maximum outer diameter to the minimum outer diameter may be a real number equal to or greater than 1.

Example embodiment 1: a semiconductor structure includes a substrate, a plurality of active channels and a source/drain layer. The plurality of active channels are disposed on the substrate and vertically stacked to each other, wherein each active channel has a lateral surface. The source/drain layer covers the lateral surfaces of the active channels. The source/drain layer has a maximum outer diameter and a minimum outer diameter, and a ratio of the maximum outer diameter to the minimum outer diameter is less than 1.1.

Example embodiment 2 based on Example embodiment 1: the source/drain layer is a single and contiguous layer.

Example embodiment 3 based on Example embodiment 1: the source/drain layer includes a plurality of sub-source/drain portions separated from each other.

Example embodiment 4 based on Example embodiment 1: the semiconductor structure further includes a metal gate and an inner spacer. The metal gate is disposed on the active channels and has a lateral surface. The inner spacer is disposed adjacent to the lateral surface of the metal gate and has a lateral surface. The source/drain layer is disposed on a portion of the lateral surface of the inner spacer.

Example embodiment 5 based on Example embodiment 4: the semiconductor structure further includes a plurality of the inner spacers. The source/drain layer is disposed on the lateral surfaces of the inner spacers.

Example embodiment 6 based on Example embodiment 1: the source/drain layer comprises a source/drain portion formed on a lateral surface of one of the active channels, and the source/drain portion is formed of silicon germanium (SiGe) or SiGe with dopant Arsenic (As) or Phosphorus (P).

Example embodiment 7 based on Example embodiment 1: the semiconductor structure further includes a metal gate, a gate spacer a protection layer. The metal gate is disposed on the active channels. The gate spacer is disposed on a lateral surface of the metal gate. The protection layer is disposed above the topmost active channel and between the metal gate and the gate spacer. The source/drain layer extends toward the protection layer but not extending to the protection layer.

Example embodiment 8: a semiconductor structure includes a substrate, a plurality of active channels and a source/drain layer. The substrate has a front surface and an epitaxial crystal orientation of (110) indicated by a miller index, wherein the epitaxial crystal orientation is perpendicular to the front surface. The active channels are disposed on the substrate and vertically stacked to each other, wherein each active channel has a lateral surface. The source/drain layer covers the lateral surfaces of the active channels.

Example embodiment 9 based on Example embodiment 8: the source/drain layer has a maximum outer diameter and a minimum outer diameter, and a ratio of the maximum outer diameter to the minimum outer diameter is less than 1.1.

Example embodiment 10 based on Example embodiment 8: the source/drain layer is a single and contiguous layer.

Example embodiment 11 based on Example embodiment 8: the source/drain layer includes a plurality of sub-source/drain portions separated from each other.

Example embodiment 12 based on Example embodiment 8: the semiconductor structure further includes a metal gate and an inner spacer. The metal gate is disposed on the active channels and has a lateral surface. The inner spacer is disposed adjacent to the lateral surface of the metal gate and has a lateral surface. The source/drain layer is disposed on a portion of the lateral surface of the inner spacer.

Example embodiment 13 based on Example embodiment 12: the semiconductor structure further includes a plurality of the inner spacers. The source/drain layer is disposed on the lateral surfaces of the inner spacers.

Example embodiment 14 based on Example embodiment 8: the source/drain layer comprises a source/drain portion formed on a lateral surface of one of the active channels, the source/drain portion is formed of SiGe or SiGe with dopant As or P.

Example embodiment 15 based on Example embodiment 8: the semiconductor structure further includes a metal gate, a gate spacer a protection layer. The metal gate is disposed on the active channels. The gate spacer is disposed on a lateral surface of the metal gate. The protection layer is disposed above the topmost active channel and between the metal gate and the gate spacer. The source/drain layer extends toward the protection layer but not extending to the protection layer.

Example embodiment 16: a manufacturing method for a semiconductor structure includes the following steps: providing a substrate, wherein the substrate has a front surface and an epitaxial crystal orientation of (110) indicated by a miller index, and the epitaxial crystal orientation is perpendicular to the front surface; forming a plurality of active channels on the substrate, wherein the active channels are vertically stacked to each other; and forming a source/drain layer to cover the lateral surfaces of the active channels.

Example embodiment 17 based on Example embodiment 16: the manufacturing method further includes: forming a plurality of the active channel layers, a plurality of silicon germanium (SiGe) layers, a protection layer and a protection layer on the substrate, wherein one of the active channel layers is located between adjacent two of the SiGe layers, the protection layer is located between the protection layer and the topmost SiGe layer; removing a portion of the active channel layers, a portion of the SiGe layers, a portion of the protection layer and a portion of the protection layer, wherein a remaining portion of the active channel layers form a plurality of the active channels, and a portion of the protection layer form a plurality of protection layers; removing a remaining portion of the SiGe layers to expose a plurality of first spaces; and removing a remaining portion of the protection layer to expose a plurality of second spaces.

Example embodiment 18 based on Example embodiment 17: the manufacturing method further includes: forming a plurality of insulation layers in the first spaces and the second spaces, wherein a plurality of recesses extend to the insulation layers from the lateral surfaces of the active chancels; forming a plurality of inner spacers in the recesses; and removing the insulation layers after the source/drain layer is formed.

Example embodiment 19 based on Example embodiment 16: in forming the source/drain layer to cover the lateral surfaces of the active channels, the source/drain layer is a single and contiguous layer. The source/drain layer has a maximum outer diameter and a minimum outer diameter, and a ratio of the maximum outer diameter to the minimum outer diameter is less than 1.1.

Example embodiment 20 based on Example embodiment 16: in forming the source/drain layer to cover the lateral surfaces of the active channels, the source/drain layer includes a plurality of sub-source/drain portions separated from each other. One of the sub-source/drain portion has a maximum outer diameter and a minimum outer diameter, and a ratio of the maximum outer diameter to the minimum outer diameter is less than 1.1.

Example embodiment 21 based on Example embodiment 1: the source/drain layer has an upper surface and a lateral surface, and a minimum included angle between a tangential of a point of the lateral surface and the upper surface is equal to or greater than 60 degrees.

Example embodiment 21 based on Example embodiment 1: the source/drain layer has an upper surface and a lateral surface, and a minimum included angle between a tangential of a point of the lateral surface and the upper surface is equal to or greater than 60 degrees.

Example embodiment 22 based on Example embodiment 8: the source/drain layer has an upper surface and a lateral surface, and a minimum included angle between a tangential of a point of the lateral surface and the upper surface is equal to or greater than 60 degrees.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a plurality of active channels on the substrate and vertically stacked to each other, wherein each active channel has a lateral surface; and
a source/drain layer covering the lateral surfaces of the active channels;
wherein the source/drain layer has a maximum outer diameter and a minimum outer diameter, and a ratio of the maximum outer diameter to the minimum outer diameter is less than 1.1.

2. The semiconductor structure according to claim 1, wherein the source/drain layer is a single and contiguous layer.

3. The semiconductor structure according to claim 1, wherein the source/drain layer comprises:
a plurality of sub-source/drain portions separated from each other.

4. The semiconductor structure according to claim 1, further comprising:
a metal gate on the active channels and having a lateral surface; and
an inner spacer disposed adjacent to the lateral surface of the metal gate and having a lateral surface;
wherein the source/drain layer is disposed on a portion of the lateral surface of the inner spacer.

5. The semiconductor structure according to claim 4, further comprising:
a plurality of the inner spacers;
wherein the source/drain layer is disposed on the lateral surfaces of the inner spacers.

6. The semiconductor structure according to claim 1, wherein the source/drain layer comprises a source/drain portion formed on a lateral surface of one of the active channels, the source/drain portion is formed of silicon germanium (SiGe) or SiGe with dopant Arsenic (As) or Phosphorus (P).

7. The semiconductor structure according to claim 1, further comprising:
a metal gate on the active channels;
a gate spacer on a lateral surface of the metal gate; and
a protection layer disposed above the topmost active channel and between the metal gate and the gate spacer;
wherein the source/drain layer extends toward the protection layer but not extending to the protection layer.

8. A semiconductor structure, comprising:
a substrate having a front surface and an epitaxial crystal orientation of (110) indicated by a miller index, wherein the epitaxial crystal orientation is perpendicular to the front surface;
a plurality of active channels on the substrate and vertically stacked to each other, wherein each active channel has a lateral surface; and
a source/drain layer covering the lateral surfaces of the active channels.

9. The semiconductor structure according to claim 8, wherein the source/drain layer has a maximum outer diameter and a minimum outer diameter, and a ratio of the maximum outer diameter to the minimum outer diameter is less than 1.1.

10. The semiconductor structure according to claim 8, wherein the source/drain layer is a single and contiguous layer.

11. The semiconductor structure according to claim 8, wherein the source/drain layer comprises:
a plurality of sub-source/drain portions separated from each other.

12. The semiconductor structure according to claim 8 further comprising:
a metal gate in the active channels and having a lateral surface; and
an inner spacer over the lateral surface of the metal gate and having a lateral surface;
wherein the source/drain layer is disposed on the lateral surface of the inner spacer.

13. The semiconductor structure according to claim 12, further comprising:
a plurality of the inner spacers;
wherein the source/drain layer is disposed on the lateral surfaces of the inner spacers.

14. The semiconductor structure according to claim 8, wherein the source/drain layer comprises a source/drain portion formed on a lateral surface of one of the active channels, the source/drain portion is formed of SiGe or SiGe with dopant As or P.

15. The semiconductor structure according to claim 8, further comprising:
a metal gate on the active channels;
a gate spacer on a lateral surface of the metal gate; and
a protection layer disposed above the topmost active channel and between the metal gate and the gate spacer;
wherein the source/drain layer extends toward the protection layer but not extending to the protection layer.

16. A manufacturing method for a semiconductor structure, comprising:
providing a substrate, wherein the substrate has a front surface and an epitaxial crystal orientation of (110) indicated by a miller index, and the epitaxial crystal orientation is perpendicular to the front surface;
forming a plurality of active channels on the substrate, wherein the active channels are vertically stacked to each other; and
forming a source/drain layer to cover the lateral surfaces of the active channels.

17. The manufacturing method according to claim 16, further comprising:
forming a plurality of the active channel layers, a plurality of SiGe layers, a protection layer and a protection layer on the substrate, wherein one of the active channel layers is located between adjacent two of the SiGe layers, the protection layer is located between the protection layer and the topmost SiGe layer;
removing a portion of the active channel layers, a portion of the SiGe layers, a portion of the protection layer and a portion of the protection layer, wherein a remaining portion of the active channel layers form a plurality of the active channels, and a portion of the protection layer form a plurality of protection layers;
removing a remaining portion of the SiGe layers to expose a plurality of first spaces; and
removing a remaining portion of the protection layer to expose a plurality of second spaces.

18. The manufacturing method according to claim 17, further comprising:
forming a plurality of insulation layers in the first spaces and the second spaces, wherein a plurality of recesses extend to the insulation layers from the lateral surfaces of the active chancels;
forming a plurality of inner spacers in the recesses; and
removing the insulation layers after the source/drain layer is formed.

19. The manufacturing method according to claim 16, wherein in forming the source/drain layer to cover the lateral surfaces of the active channels, the source/drain layer is a single and contiguous layer;
wherein the source/drain layer has a maximum outer diameter and a minimum outer diameter, and a ratio of the maximum outer diameter to the minimum outer diameter is less than 1.1.

20. The manufacturing method according to claim 16, wherein in forming the source/drain layer to cover the lateral surfaces of the active channels, the source/drain layer comprises a plurality of sub-source/drain portions separated from each other;
wherein one of the sub-source/drain portion has a maximum outer diameter and a minimum outer diameter, and a ratio of the maximum outer diameter to the minimum outer diameter is less than 1.1.
